(19) United States
(12) Patent Application Publication
(10) Pub. No.: US 2015/0095747 A1
(43) Pub. Date: Apr. 2, 2015

(54) METHOD FOR DATA RECOVERY

(71) Applicants: Itzhak Tamo, Tel-Aviv (IL); Alexander Barg, Bethesda, MD (US)

(72) Inventors: Itzhak Tamo, Tel-Aviv (IL); Alexander Barg, Bethesda, MD (US)

(21) Appl. No.: 14/499,349

(22) Filed: Sep. 29, 2014

Related U.S. Application Data
(60) Provisional application No. 61/884,768, filed on Sep. 30, 2013.

(51) Int. Cl. H03M 13/15; H03M 13/00

(52) U.S. Cl. CPC H03M 13/151; H03M 13/617
USPC 714/781

(57) ABSTRACT

A method for encoding multiple data symbols, the method may include receiving or calculating, by a computerized system, multiple (k) input data symbols; wherein the multiple input data symbols belong to a finite field F of order q; q being a positive integer that may exceed n; mapping the multiple input data symbols, by an injective mapping function, to a set of encoding polynomials; wherein the set of encoding polynomials comprises at least one encoding polynomial; and constructing a plurality (n) of encoded symbols that form multiple (t) recovery sets by evaluating the set of encoding polynomials at points of pairwise disjoint subsets (A₁, . . . , Aₜ) of the finite field F; wherein each recovery set is associated with one of the pairwise disjoint subsets of the finite field F.

### RELATED APPLICATIONS

This application claims priority from U.S. provisional patent Ser. No. 61/884,768 filing date Sep. 30, 2013 which is incorporated herein by reference.

### BACKGROUND OF THE INVENTION

One of the side effects of the information era is the enormous amounts of data generated and stored every day. While in most applications data loss is intolerable, no storage system can provide complete immunity from data loss failure, necessitating the addition of redundancy to the storage scheme in order to provide enough data reliability and ensure data recovery. Moreover, since the amount of data increases faster than the infrastructure, cheap storage commodities are harnessed together to produce large scale storage systems. However, this solution further increases the need to protect and recover the lost data, since cheap devices are much less reliable, and are often prone to failures and data loss.

The most common data scheme used is replication. Namely, a data block to be stored is replicated several times and is stored on distinct storage devices. This data management scheme has several desirable advantages. First and foremost, its simplicity in implementation and maintenance plays a crucial role in favoring this solution over the others. Second, it enables information to be easily accessible coupled with an easy recovery process. Simply, in order to recover a lost block, one needs to access its copy. On the other hand, this scheme entails a huge overhead in storage since it doubles or triples the amount of storage space compared to the original amount of data. Combined with present-day data being stored, this solution becomes too costly both financially and environmentally, and burdensome in a myriad of other aspects.

Another data management scheme that is being used is the well-known Erasure-Correcting Codes (ECCs). Namely, given k data blocks to be stored, the system produces extra n−k data blocks (typically termed as parity) to be stored. The system then stores the total n blocks on distinct n devices in order to increase reliability in case of disk failure. This scheme can tolerate any n−k failures of data blocks out of the n stored blocks. Clearly, compared to the replication scheme, there is a negligible reduction in the overhead. However, a major drawback of this scheme is the access parameter that is discussed below.

The access parameter, as discussed above in reference to the ECCs, is defined to be the amount of information that is read during the recovery process. In case of a detection of a failed data block in the system in ECCs, the controller performs a data recovery process. Namely, it uses the redundant nature of the data management scheme in order to recover the lost information. This is done by accessing and reading some other data blocks stored in the system. Typically the lost information is a linear function of the read data blocks; hence by performing linear operations on it, one can recover the lost data.

Although ECCs have high resiliency to erasures (can tolerate any n−k failures), by far the most common scenario is a single block failure which incurs k blocks accesses and reads. In other words, the access parameter is k, which is a factor of k times the amount of data being recovered. A large access parameter translates to a large overload on the data access and transmission within the storage system and/or the data center which is particularly pronounced if the information is stored in a distributive manner, and the information needs to be transmitted across systems and servers. These reads and transmissions can clog the system's network, and thus reduce system performance and add to overall costs. In summary, one would like to implement a data management scheme that has high resiliency to failures, low storage overhead together with low access parameter during the recovery process of information loss.

The following references provide a view of the prior art:
[1] N. Alon and J. Spencer, The probabilistic method, J. Wiley & Sons, Hoboken, N.J., 2008.
[2] A. Barg and G. Zémor, Concatenated codes: Serial and parallel, IEEE Trans. Inform. Theory 51 (2005), no. 5, 1625-1634.
[3] M. Blaum, J. L. Hafner, and S. Hetzler, Partial-mds codes and their application to RAID type of architectures, IEEE Trans. Inform. Theory 59 (2013), no. 7, 4510-4519.
[4] V. R. Cadambe, C. Huang, S. A. Jafar, and J. Li, Optimal repair of mds codes in distributed storage via subspace interference alignment, arXiv:1106.1250.
[5] V. Cadambe and A. Mazumdar, An upper bound on the size of locally recoverable codes, arXiv:1308.3200.
[6] A. G. Dimakis, P. B. Godfrey, Y. Wu, M. J. Wainwright, and K. Ramchandran, Network coding for distributed storage systems, IEEE Trans. Inform. Theory 56 (2010), no. 9, 4539-4551.
[7] M. Forbes and S. Yekhanin, On the locality of codeword symbols in non-linear codes, arXiv:1303.3921.
[8] P. Gopalan, C. Huang, B. Jenkins, and S. Yekhanin, Explicit maximally recoverable codes with locality, arXiv:1307.4150.
[9] P. Gopalan, C. Huang, H. Simitci, and S. Yekhanin, On the locality of codeword symbols, IEEE Trans. Inform. Theory 58 (2011), no. 11, 6925-6934.
[10] J. Han and L. A. Lastras-Montano, Reliable memories with subline accesses, Proc. IEEE Internat. Sympos. Inform. Theory, 2007, pp. 2531-2535.
[11] C. Huang, M. Chen, and J. Li, Pyramid codes: Flexible schemes to trade space for access efficiency in reliable data storage systems, Sixth IEEE International Symposium on Network Computing and Applications, 2007, pp. 79-86.
[12] G. M. Kamath, N. Prakash, V. Lalitha, and P. V. Kumar, Codes with local regeneration, arXiv:1211.1932.
[13] O. Khan, R. Burns, J. Plank, and C. Huang, In search of I/O-optimal recovery from disk failures, Proc. 3rd USENIX conference on “Hot topics in storage and file systems”, 2011, 5pp. Available online at https:www.usenix.org/legacy/events/hotstorage11.
[14] F. J. MacWilliams and N. J. A. Sloane, The theory of error-correcting codes, North-Holland, Amsterdam, 1991.
[15] A. Mazumdar, V. Chandar, and G. W. Wornell, Update efficiency and local repairability limits for capacity-achieving codes, arXiv:1305:3224.
[16] F. Oggier and A. Datta, Self-repairing homomorphic codes for distributed storage systems, Proc. 2011 IEEE INFOCOM, 2011, pp. 1215-1223.
[17] L. Pamies-Juarez, H. D. L. Hollmann, and F. E. Oggier, Locally repairable codes with multiple repair alternatives, arXiv:1302.5518.
[18] D. S. Papailiopoulos and A. G. Dimakis, Locally repairable codes, Information Theory Proceedings (ISIT), 2012 IEEE International Symposium on, 2012, pp. 2771-2775.
[19] D. S. Papailiopoulos, A. G. Dimakis, and V. R. Cadambe, Repair optimal erasure codes through hadamard designs, Proc. 49th Annual Allerton Conf. Commun., Control, Comput., 2011, pp. 1382-1389.
[20] D. S. Papailiopoulos, J. Luo, A. G. Dimakis, C. Huang, and J. Li, Simple regenerating codes: Network coding for cloud storage, Proc. IEEE INFOCOM, 2012, pp. 2801-2805.
[21] N. Prakash, G. M. Kamath, V. Lalitha, and P. V. Kumar, Optimal linear codes with a local-error-correction property, Proc. 2012 IEEE Internat. Sympos. Inform. Theory, IEEE, 2012, pp. 2776-2780.
[22] K. V. Rashmi, Nihar B. Shah, and Kannan Ramchandran, A piggybacking design framework for read- and download-efficient distributed storage codes, arXiv:1302.5872.
[23] K. V. Rashmi, N. B. Shah, and P. V. Kumar, Optimal exact-regenerating codes for distributed storage at the msr and mbr points via a product-matrix construction, IEEE Trans. Inform. Theory 57 (2011), no. 8, 5227-5239.
[24] N. Silberstein, A. S. Rawat, O. O. Koyluoglu, and S. Vishwanath, Optimal locally repairable codes via rank-metric codes, arXiv:1301.6331.
[25] C. Suh and K. Ramchandran, Exact-repair mds code construction using interference alignment, IEEE Trans. Inform. Theory 57 (2011), no. 3, 1425-1442.
[26] I. Tamo, D. S. Papailiopoulos, and A. G. Dimakis, Optimal locally repairable codes and connections to matroid theory, Proc. 2013 IEEE Internat. Sympos. Inform. Theory, 2013, pp. 1814-1818.
[27] I. Tamo, Z. Wang, and J. Bruck, Zigzag codes: MDS array codes with optimal rebuilding, IEEE Trans. Inform. Theory 59 (2013), no. 3, 1597-1616.

### SUMMARY OF THE INVENTION

The invention is concerned with methods of Locally Recoverable Coding (LRC) of data for storage and other applications. The invention comprises several methods of storing and/or transmitting data blocks that enable resilience to erasures and errors. The affected data can be recovered in a local manner by accessing a small number of non-corrupted data blocks, hence reducing the access and storage overhead. An important feature of the invention is high erasure resilience including in some cases the best possible resiliency to erasures for a given amount of overhead data blocks and the resulting extra storage space.

In all of the methods proposed, data blocks are viewed as elements of a finite field of size at least n, where n is the number of data blocks in the encoding, including fields of size that are a power of 2.

The first of the proposed methods adds n−k extra data blocks for each group of k payload (input) data blocks, such that the n data blocks of the encoding can be partitioned into t sets A₁, A₂, . . . , Aₜ of data blocks, for some desired integer t. Each set Aᵢ is of cardinality nᵢ, and it forms a codeword in an erasure correcting code, termed local code, that can tolerate the maximum number of erasures for the given amount kᵢ of the encoded data. In other words, any single data block from the set Aᵢ can be recovered from any kᵢ data blocks out of the remaining nᵢ−1 data blocks in the set Aᵢ. Hence, this method provides large flexibility in recovering each data block during the recovery process.

In particular, the invention proposes an encoding method concerned with a special set of parameters wherein all the local codes are of the same cardinality and the same length, namely for any i, the parameters nᵢ and kᵢ are equal to some fixed values N and K. In this case, the invention provides the largest possible erasure and error resilience for the given amount of overhead data blocks required by the encoding method. The second method provides two distinct ways of constructing the encoding with several disjoint recovering sets for each data block. More formally, for given k data blocks, the method produces n−k extra data blocks such for each data block a there are t disjoint subsets of data blocks A₁, . . . , Aₜ of the set of all n blocks associated with it. The sets Aᵢ can be of different cartinalities. Furthermore, the data block a can be recovered from the data in each of the sets Aᵢ.

Therefore, this method provides t distinct ways of recovering an erased data block, where each of the recoveries can be performed independently of the others.

According to an embodiment of the invention there may be provided a non-transitory computer readable medium that stores instructions for encoding multiple data symbols, wherein the instruction once executed by a computer, cause the computer to execute the stages of: receiving or calculating multiple (k) input data symbols; wherein the multiple input data symbols belong to a finite field F of order q; q being a positive integer; mapping the multiple input data symbols, by an injective mapping function, to a set of encoding polynomials; wherein the set of encoding polynomials comprises at least one encoding polynomial; and constructing a plurality (n) of encoded symbols that form multiple (t) recovery sets by evaluating the set of encoding polynomials at points of pairwise disjoint subsets (A₁, . . . , Aₜ) of the finite field F; wherein each recovery set is associated with one of the pairwise disjoint subsets of the finite field F.

According to an embodiment of the invention there may be provided a computerized system such as a computer that may include a memory and a processor, wherein the processor may be arranged to: receive or calculate multiple (k) input data symbols; wherein the multiple input data symbols belong to a finite field F of order q; q being a positive integer; map the multiple input data symbols, by an injective mapping function, to a set of encoding polynomials; wherein the set of encoding polynomials comprises at least one encoding polynomial; and construct a plurality (n) of encoded symbols that form multiple (t) recovery sets by evaluating the set of encoding polynomials at points of pairwise disjoint subsets (A₁, . . . , Aₜ) of the finite field F; wherein each recovery set is associated with one of the pairwise disjoint subsets of the finite field F.

According to an embodiment of the invention there may be provided a method for encoding multiple data symbols, the method may include receiving or calculating, by a computerized system, multiple (k) input data symbols; wherein the multiple input data symbols belong to a finite field F of order q; q being a positive integer; mapping the multiple input data symbols, by an injective mapping function, to a set of encoding polynomials; wherein the set of encoding polynomials comprises at least one encoding polynomial; and constructing a plurality (n) of encoded symbols that form multiple (t) recovery sets by evaluating the set of encoding polynomials at points of pairwise disjoint subsets (A₁, . . . , Aₜ) of the finite field F; wherein each recovery set is associated with one of the pairwise disjoint subsets of the finite field F.

The injective mapping may map multiple (k) elements of the finite field F to a product of multiple (t) spaces of polynomials, wherein a dimension of the i'th space of polynomials does not exceed the size of the i'th pairwise disjoint subset of the finite field F.

The injective mapping may map elements of the finite field F to a direct sum of spaces.

X is a variable, index i ranges between 1 and t, an i'th recovery set of multiple (t) recovery sets has a size nᵢ, index r does not exceed (nᵢ−1), a space (F [symbol] [x]) of polynomials that are constant on each of the pairwise disjoint subsets (A₁, . . . , Aₜ) of the finite field F. A direct sum of spaces of polynomials equals ⊕ᵢ₌₀^{r-1} F [symbol] [x]xⁱ.

The method may include reconstructing a failed encoded symbol of a certain recovery set by processing non-failed encoded symbols of the certain recovery set.

The processing may include calculating, for each recovery set of the multiple recovery sets, a recovery set that is responsive to (a) elements that belong to the recovery set, (b) an annihilator polynomial of the recovery set, and (c) a mapped polynomial to which the recovery set is mapped to by an injective mapping function.

For every value of i that ranges between 1 and t, the symbols may include the i'th recovery set are calculated using the Chinese Remainder Theorem algorithm as follows:

$${f}_{i} ( β ) = {\sum }_{i = 1}^{t} \{ {\sum }_{β ∈ {A}_{i}} \frac{{M}_{i} ( β )}{{\prod }_{m \neq i} {G}_{m} ( β )} {\prod }_{γ \neq β i} \frac{x - γ}{β - γ} {\prod }_{m \neq i} {G}_{m} ( β ) \} ;$$

wherein index i ranges between 1 and t, for all element β belonging to an i'th pairwise disjoint subset of the finite field F, the injective mapping function may map the multiple input data symbols to a t-tuple of polynomials M₁(x), . . . , Mₜ(x), and Gᵢ(x) is the annihilator polynomial of the i'th recovery set, i=1, . . . , t.

At least two recovery sets of the multiple recovery sets may differ from each other by size.

All recovery sets of the multiple recovery sets may have a same size.

All recovery sets of the multiple recovery sets may have a size that equals r+1, wherein t equals n/(r+1), wherein r exceeds one and is smaller than k.

According to an embodiment of the invention r+1 divides n and r divides k.

The method may include reconstructing at least two failed encoded symbols by processing non-failed encoded symbols.

The method may include calculating an encoding polynomial in response to r coefficient polynomials.

The method may include calculating an i'th coefficient polynomial fᵢ (x) by

$${f}_{i} ( x ) = {\sum }_{j = 0}^{\frac{k}{r} - 1} {a}_{ij} {g ( x )}^{j} ,$$

i=0, . . . , r−1, wherein g(x) is a polynomial that is constant on each of the recovery sets; and calculating the encoding polynomial fₐ(x) by

$${f}_{a} ( x ) = {\sum }_{i = 0}^{r - 1} {f}_{i} ( x ) {x}^{i} .$$

The mapping and the constructing may include multiplying a k-dimensional vector that may include the multiple input symbols by an encoding matrix G that has k rows and n columns and is formed of elements of the finite field F.

The mapping and the constructing may include multiplying a k-dimensional vector that may include the multiple input symbols by an encoding matrix G′ that has k rows and n columns, wherein encoding matrix G′ equals a product of a multiplication of matrices A, G and D, wherein matrix G has k rows and n columns and is formed of elements of the finite field, matrix A has k rows and k columns and is an invertible matrix formed of elements of the finite field, and matrix D is a diagonal matrix.

Each pairwise disjoint subset may include (r+ρ−1) elements, wherein there are

$$\frac{n}{r + ρ - 1}$$

pairwise disjoint subsets, wherein ρ≧2 is a natural number, wherein a locality of each recovery set is r, wherein each recovery set includes (r+ρ−1) encoded symbols, wherein x is a variable, wherein t=n/(r+ρ−1), wherein for a polynomial g(x) of a degree (r+ρ+1) that is constant on t pairwise disjoint subsets, the injective mapping may map elements from the finite field F to a linear space of polynomials over the finite field F spanned by the polynomials g(x)^{j}xⁱ for all j=0, . . . ,

$$\frac{k}{r} - 1 ,$$

i=0, . . . , r−1.

The injective mapping function may be a first mapping function, the recovery sets may be first recovery sets; the set of encoding polynomials may be a first set of encoding polynomials, the encoded symbols may be first encoded symbols; and the method may include mapping the first encoded symbols, by a second injective mapping function, to a second set of encoding polynomials; and constructing a plurality (n) of second encoded symbols that form multiple (t) second recovery sets by evaluating the second set of encoding polynomials at points of the pairwise disjoint subsets of the finite field F; wherein each second recovery set is associated with one of the pairwise disjoint subsets of the finite field F.

The injective mapping function may be a current mapping function, the recovery sets are current recovery sets; the set of encoding polynomials may be a current set of encoding polynomials, the encoded symbols are current encoded symbols; t exceeds one; x may be a positive integer that ranges between 1 and (t−1); the method may include repeating for x times the stages of: mapping the current encoded symbols, by a next injective mapping function, to a next set of encoding polynomials; and constructing a plurality (n) of next encoded symbols that form multiple (t) next recovery sets by evaluating the next set of encoding polynomials at points of the pairwise disjoint subsets of the finite field F; each next recovery set is associated with one of the pairwise disjoint subsets of the finite field F.

At least two recovery sets may include content for reconstruction of a same encoded data symbol.

According to an embodiment of the invention there may be provided a non-transitory computer readable medium that stores instructions for encoding multiple data symbols, wherein the instruction once executed by a computer, cause the computer to execute the stages of receiving or calculating multiple (k) input data symbols; wherein the multiple symbols belongs to a finite field F; and processing the multiple symbols using a Chinese Remainder Theorem algorithm to provide a plurality (n) of encoded symbols that form multiple (t) recovery sets; wherein each of the recovery set is associated with a pairwise disjoint subset of the finite field F.

According to an embodiment of the invention there may be provided a computerized system such as a computer that may include a memory and a processor, wherein the processor may be arranged to receive or calculate multiple (k) input data symbols; wherein the multiple symbols belongs to a finite field F; and process the multiple symbols using a Chinese Remainder Theorem algorithm to provide a plurality (n) of encoded symbols that form multiple (t) recovery sets; wherein each of the recovery set is associated with a pairwise disjoint subset of the finite field F.

According to an embodiment of the invention there may be provided a method for encoding multiple data symbols, the method may include receiving or calculating, by a computerized system, multiple (k) input data symbols; wherein the multiple symbols belongs to a finite field F; and processing, by the computerized system, the multiple symbols using a Chinese Remainder Theorem algorithm to provide a plurality (n) of encoded symbols that form multiple (t) recovery sets; wherein each of the recovery set is associated with a pairwise disjoint subset of the finite field F.

The method may include reconstructing a failed encoded symbol of a certain recovery set by processing non-failed encoded symbols of the certain recovery set.

N may not exceed the number of elements of the finite field F.

The processing may include calculating, for each recovery set of the multiple recovery sets, a recovery set that is responsive to (a) elements that belong to the recovery set, (b) an annihilator polynomial of the recovery set, and (c) a mapped polynomial to which the recovery set is mapped to by an injective mapping function.

For every value of i that ranges between 1 and t, an i'th recovery set may be calculated by:

$${f}_{i} ( β ) = {\sum }_{i = 1}^{t} \{ {\sum }_{β ∈ {A}_{i}} \frac{{M}_{i} ( β )}{{\prod }_{m \neq i} {G}_{m} ( β )} {\prod }_{γ \neq β i} \frac{x - γ}{β - γ} {\prod }_{m \neq i} {G}_{m} ( β ) \}$$

wherein index i ranges between 1 and t, wherein β belongs to the i'th recovery set, the injective mapping function may map the multiple input data symbols to t-tuple of polynomials M₁(x), . . . , Mₜ(x), and Gᵢ(x) is the annihilator polynomial of the i'th recovery set.

At least two recovery sets of the multiple recovery sets may differ from each other by size.

All recovery sets of the multiple recovery sets may have a same size.

According to an embodiment of the invention there may be provided a non-transitory computer readable medium that stores instructions for encoding multiple data symbols, wherein the instruction once executed by a computer, cause the computer to execute the stages of receiving or calculating, by a computerized system, multiple (k) input data symbols; wherein the multiple input data symbols belong to a finite field F of order q; processing the multiple (k) data symbols to provide multiple (n) encoded data symbols that form multiple (t) recovery sets; and reconstructing a failed encoded symbol of the multiple (n) encoded data symbols; wherein the reconstructing may include attempting to reconstruct the failed encoded symbol by utilizing non-failed encoded symbols of at least two recovery sets that are associated with the failed encoded symbol; wherein the at least two recovery sets belong to the multiple recovery sets.

According to an embodiment of the invention there may be provided a computerized system such as a computer that may include a memory and a processor, wherein the processor may be arranged to receive or calculate multiple (k) input data symbols; wherein the multiple input data symbols belong to a finite field F of order q, process the multiple (k) data symbols to provide multiple (n) encoded data symbols that form multiple (t) recovery sets; and reconstruct a failed encoded symbol of the multiple (n) encoded data symbols; wherein the reconstructing may include attempting to reconstruct the failed encoded symbol by utilizing non-failed encoded symbols of at least two recovery sets that are associated with the failed encoded symbol; wherein the at least two recovery sets belong to the multiple recovery sets.

According to an embodiment of the invention there may be provided a method that may include receiving or calculating, by a computerized system, multiple (k) input data symbols; wherein the multiple input data symbols belong to a finite field F of order q; processing the multiple (k) data symbols to provide multiple (n) encoded data symbols that form multiple (t) recovery sets; and reconstructing a failed encoded symbol of the multiple (n) encoded data symbols; wherein the reconstructing may include attempting to reconstruct the failed encoded symbol by utilizing non-failed encoded symbols of at least two recovery sets that are associated with the failed encoded symbol; wherein the at least two recovery sets belong to the multiple recovery sets.

The reconstructing may include: performing a first attempt to reconstruct the failed encoded symbol by utilizing non-failed encoded symbols of a first recovery set of the at least two recovery sets; determining whether the first attempt failed; and performing a second attempt to reconstruct the failed encoded symbol by utilizing non-failed encoded symbols of a second recovery set of the at least two recovery sets if it is determined that the first attempt failed.

The number of recovery sets may exceed two and the reconstructing may include performing a first attempt to reconstruct the failed encoded symbol by utilizing non-failed encoded symbols of a first recovery set of the at least two recovery sets; determining whether the first attempt failed; and performing multiple additional attempts to reconstruct the failed encoded symbol by utilizing non-failed encoded symbols of a multiple other recovery set of the at least two recovery sets if it is determined that the first attempt failed.

Any combination of any stage of any method illustrated in the specification may be provided. The same applies to combinations of instructions stored in the computer readable medium and to operations executed by a processor.

According to an embodiment of the invention there may be provided a non-transitory computer readable medium that stores instructions for encoding multiple data symbols, wherein the instruction once executed by a computer, cause the computer to execute the stages of reconstructing a failed symbol using non-failed symbols that were encoded using any of the methods illustrated in the specification.

According to an embodiment of the invention there may be provided a method that may include reconstructing a failed symbol using non-failed symbols that were encoded using any of the methods illustrated in the specification.

According to an embodiment of the invention there may be provided a computerized system such as a computer that may include a memory and a processor, wherein the processor may be arranged to reconstruct a failed symbol using non-failed symbols that were encoded using any of the methods illustrated in the specification.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 is a flow diagram of the data replication management scheme that is widely used in current storage systems;

FIG. 2 is a flow diagram of the Erasure-Correcting Code (ECC) data management scheme that becomes more widespread due to the small storage overhead compared to the replication method;

FIG. 3 is a block diagram of a storage system;

FIG. 4 is a flow diagram of the operations performed by the Controller of Data Management Scheme according to an embodiment of the invention;

FIG. 5 is a detailed flow diagram of the write and the recovery operations performed by the Controller of Data Management Scheme according to an embodiment of the invention;

FIG. 6 is a description the first Locally Recoverable Code (LRC) method according to an embodiment of the invention;

FIG. 7 is a flow diagram of the operation of Data Management Scheme with Multiple Recovering Sets according to an embodiment of the invention;

FIG. 8 is a diagrammatic representation of Multiple Recovering Sets via Product Codes according to an embodiment of the invention;

FIG. 9 is a diagrammatic representation of Multiple Recovering Sets via Algebraic LRC Codes according to an embodiment of the invention;

FIG. 10 shows a block diagram of a computer system such as utilized as the Controller of Data management Scheme or host computer of FIG. 3 according to an embodiment of the invention;

FIG. 11 is an example of a suitable computing system environment in which the Locally Recoverable Coding (LRC) method may be implemented;

FIG. 12 illustrates a method according to an embodiment of the invention;

FIG. 13 illustrates a method according to an embodiment of the invention;

FIG. 14 illustrates a method according to an embodiment of the invention;

FIG. 15 illustrates a method according to an embodiment of the invention;

FIG. 16 illustrates a method according to an embodiment of the invention; and

FIG. 17 illustrates a method according to an embodiment of the invention.

### DETAILED DESCRIPTION OF THE DRAWINGS

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

Because the illustrated embodiments of the present invention may for the most part, be implemented using electronic components and circuits known to those skilled in the art, details will not be explained in any greater extent than that considered necessary as illustrated above, for the understanding and appreciation of the underlying concepts of the present invention and in order not to obfuscate or distract from the teachings of the present invention. Any reference in the specification to a method should be applied mutatis mutandis to a system capable of executing the method and should be applied mutatis mutandis to a non-transitory computer readable medium that stores instructions that once executed by a computer result in the execution of the method.

Any reference in the specification to a system should be applied mutatis mutandis to a method that may be executed by the system and should be applied mutatis mutandis to a non-transitory computer readable medium that stores instructions that may be executed by the system.

Any reference in the specification to a non-transitory computer readable medium should be applied mutatis mutandis to a system capable of executing the instructions stored in the non-transitory computer readable medium and should be applied mutatis mutandis to method that may be executed by a computer that reads the instructions stored in the non-transitory computer readable medium.

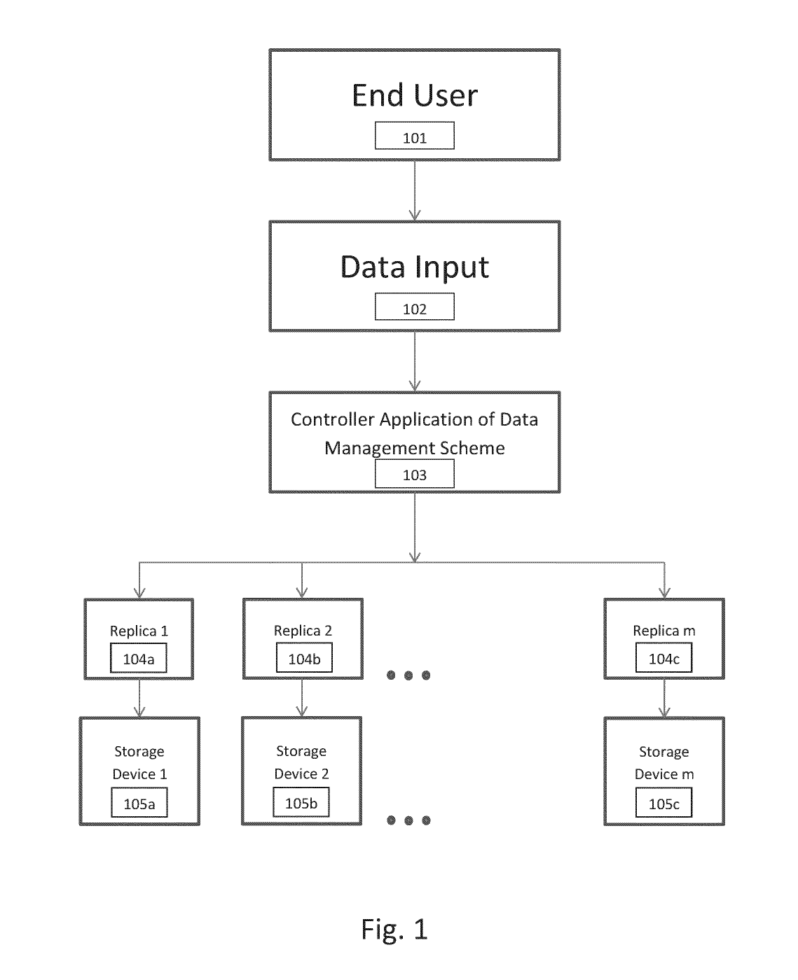

FIG. 1 shows a flow diagram of the data replication management scheme that is widely used in current storage systems. The End User (box 101) connects to the storage system, and transfers to it the Data Input (box 102) to be stored for later usage. The data is handled by the Controller Application of Data Management Scheme (box 103), which is in charge of managing the data across the storage system. Based on the configured level of data protection, m copies of the data are generated (boxes 104a, 104b, 104c). The Controller also decides on which storage devices the copies will reside. The m copies are transmitted to the m selected storage devices (boxes 105a, 105b, 105c) that store the data.

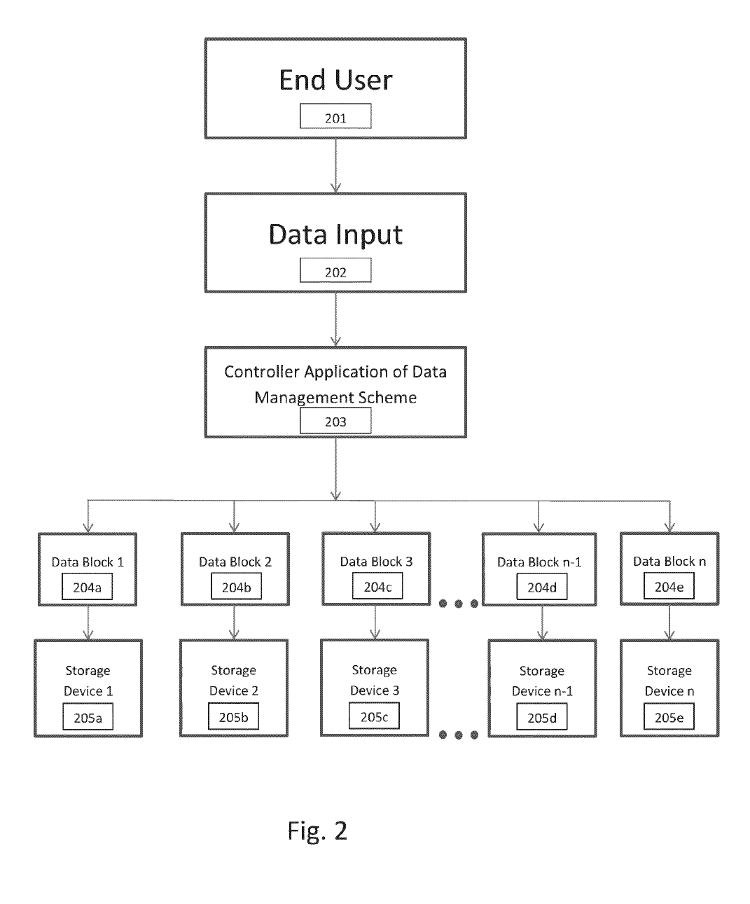

FIG. 2 shows a flow diagram of the Erasure-Correcting Code (ECC) data management scheme that represents an alternative to replication due to the small storage overhead compared to the replication method. The End User (box 201) connects to the storage system and transfers to it the Data Input (box 202) to be stored for later usage. The data is handled by the Controller Application of Data Management Scheme (box 203), which is in charge of managing the data across the storage system. Based on the configured level of data protection, the data is partitioned into k data blocks, and extra n−k data blocks are generated, forming a total of n data blocks (boxes 204a, 204b, 204c, 204d, and 204e). The Controller also decides on which storage devices the n data blocks will reside. The n data blocks are transmitted to the n chosen storage devices (boxes 205a, 205b, 205c, 205d, and 205e) that store the data.

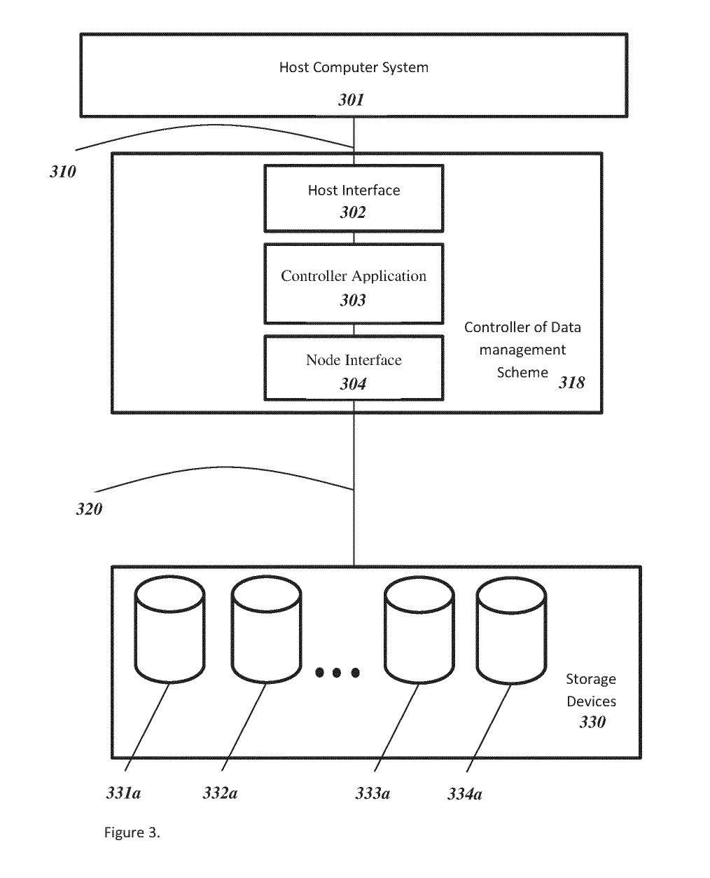

FIG. 3 (the figure and the description is prior art from patent US20120278689 A1) shows a block diagram of the storage system. A Host Computer System (box 301) communicates with the Controller of Data Management Scheme (box 318) in order to perform read and write operations. The communication is performed over a host transport medium (310) and a host interface (box 302). The host transport medium may comprise, for example, a network connection that is wired or wireless, or it may comprise a system connection such as a system bus or the like. The host interface may comprise, for example, a network interface card or other means for communications. The Storage Devices (box 330) comprise multiple nodes (331a, 332a, 333a, 334a) storing user's data and parity data generated by the Data Management Scheme. Each node may comprise a single disk drive or multiple drives. The count of nodes in box 330 can be any number according to the system resources.

The Controller of Data Management Scheme (box 318) communicates with the host computer system (box 301) over a host transport medium 310 through a host interface (box 302). The host transport medium may comprise, for example, a network connection that is wired or wireless, or it may comprise a system connection such as a system bus or the like. The host interface may comprise, for example, a network interface card or other means for communications. The Controller of Data Management Scheme (box 318) communicates with the nodes (331a, 332a, 333a, 334a) of the Storage Devices (box 330) over an array transport medium 320 through a node interface (box 304). The array transport medium may comprise, for example, a network connection that is wired or wireless, or may comprise a system connection such as a system bus or the like. The node interface may comprise, for example, a network interface card or other means for communications.

The Controller of Data Management Scheme (box 318) comprises a computer device and, as described further below, as such the Controller of Data Management Scheme includes memory and a central processor unit, providing an operating system of the Controller of Data Management Scheme. A controller application (box 303) operates in the Controller of Data Management Scheme, supported by the operating system of the Controller of Data Management Scheme, such that the controller application manages communications through the host interface (box 302) and the node interface (box 304), and also manages code generation for the write and read operations with the Storage Devices and any recovering operations upon node erasure.

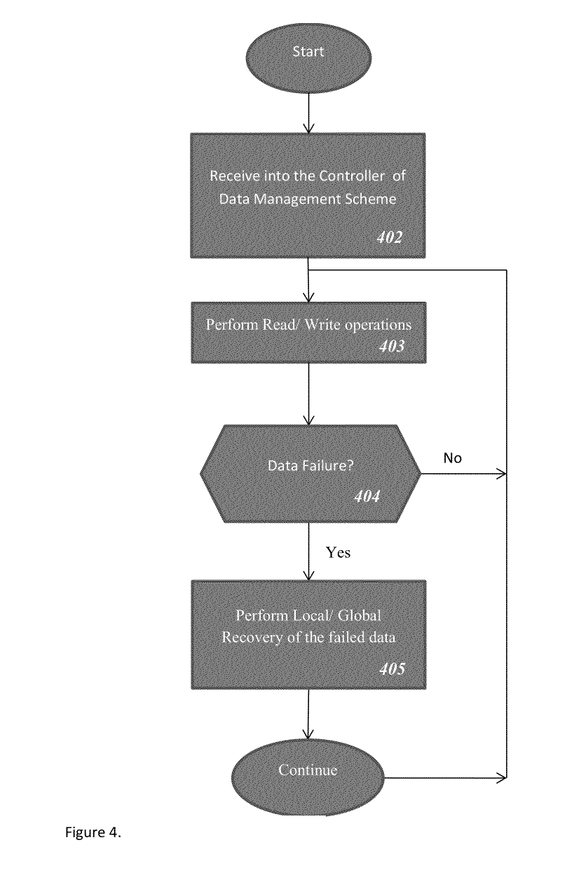

FIG. 4 shows a flow diagram of the operations performed by the Controller of Data Management Scheme (box 318 of FIG. 3). The Controller of Data Management Scheme receives the Data Management Configuration for protection against erasures and errors (box 402). This data includes the number of data blocks to be stored (typically denoted by k), the number of extra parity blocks to be generated (typically denoted by n−k), and the level of locality (typically denoted by r). Moreover, it includes the number of storage devices in the system, their capacity, location, and any other information necessary for the performance of the Controller of Data Management Scheme in the system.

After the data has been received, the Controller of Data Management Scheme can perform Read and Write operations (box 403). The write operations are performed in accordance with the principles in this disclosure, Data Management Configuration, and any predetermined features that are implemented in the Controller of Data Management Scheme.

Once a data failure occurs, the Controller of Data Management detects the event and takes appropriate actions in order to recover the failed data (box 404). The detection of a failed data can be done in several ways, for instance, during Read/Write operations or a connection loss with some of the storage devices. Upon such detection (an affirmative outcome at box 404), the Controller of Data Management Scheme performs a Local/Global recovery of the failed data (box 405) as described above, in accordance with the principles of this disclosure. If no data failure event is detected (a negative outcome at the decision box 404), the Controller of Data Management Scheme continues with Read and Write operations, as indicated by the return to perform Read/Write operations (box 403).

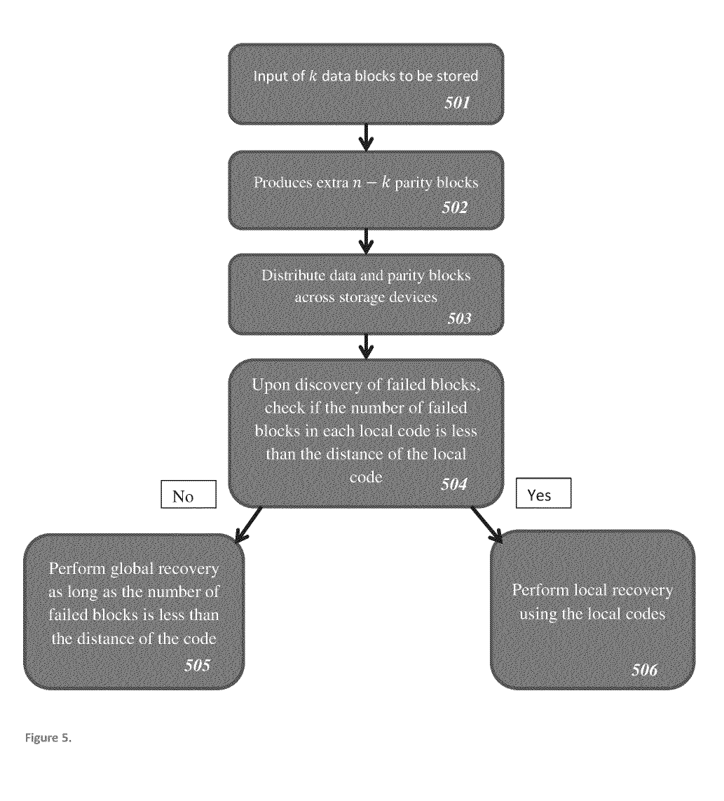

FIG. 5 shows a detailed flow diagram of the write and the recovery operations performed by the Controller of Data Management Scheme (Boxes 403-405 in FIG. 4). Upon receiving an input of k data blocks to be stored (box 501), the Controller of Data Management Scheme produces extra n−k parity blocks that will provide the resiliency to future data failures, together with the property of the local recovery (box 502). Moreover, these parity blocks are generated according to the Data Management Configuration (box 402, FIG. 4) previously provided to the Controller of Data Management Scheme. Based on the available storage devices, their storage capacity, and other parameters of the system, the Controller of Data Management Scheme makes the decision which storage devices (e.g. servers) will store each of the n data blocks of the encoding (box 503), and then it distributes the data and parity blocks across these storage devices. Typically each data block will reside on a distinct storage system in order to increase reliability and durability of the data.

In case of a data failure detected by the Controller of Data Management Scheme, the recovery process begins in order to restore the failing data. The preferred method is local recovery since it requires less time, computation, and storage resources. Hence for each failed block, the controller needs to determine whether it is possible to recover it by the local recovery method. The set of failed data blocks is partitioned according to the different local codes. Then, in each local code, local recovery of its failed blocks is possible if the number of failed data blocks is less than the local code's minimal distance (box 504). If for each local code an affirmative outcome at box 504 is received, then local recovery is performed for all the failed data blocks in accordance with the principles of this disclosure (box 506). If at least one failed data block cannot be recovered locally, namely, in one of the local codes, the number of failed data blocks is at least the minimum distance of the code, then all the failed data is recovered using global recovery, and a negative outcome is received at box 504. In such a case, it is possible to perform global recovery as long as the number of failed blocks is less than the distance of the code (box 505).

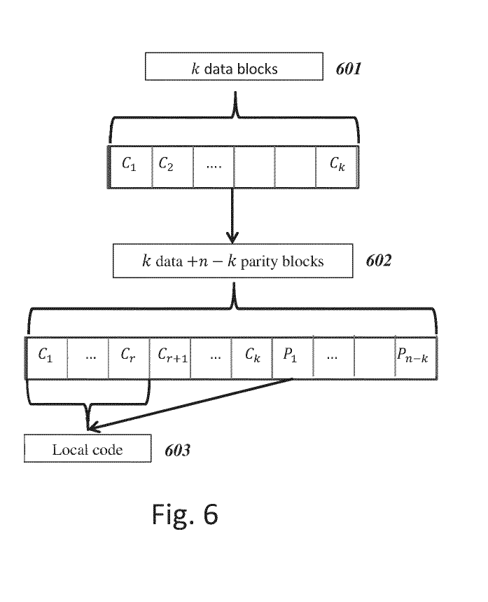

FIG. 6 describes the first Locally Recoverable Code (LRC) method described above. Upon the input of k data blocks to be stored is received by the system (box 601), where each data block is represented by the symbol Cᵢ, i=1, . . . , k, the Controller of the Data Management Scheme generates extra n−k blocks, called Parity Blocks, according to system's configuration to obtain the total of n blocks (box 602). According to the properties of the proposed data management scheme, each data block is contained in a local code of size r+1 data blocks (e.g. the data blocks in box 603). Each data block C₁, . . . , Cᵣ, P₁ can be locally recovered from the other r data blocks in the local code. For example, upon the failure of the data block C₁, the block can be recovered from the data blocks C₂, . . . , Cᵣ, P₁.

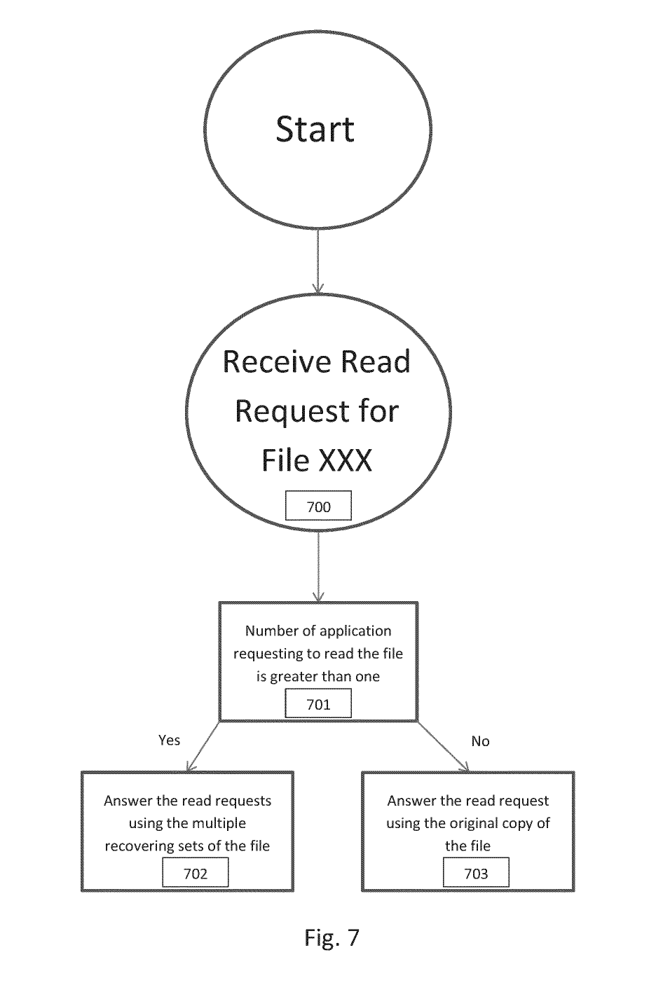

FIG. 7 shows a flow diagram of the operation of Data Management Scheme with Multiple Recovering Sets. The Controller of Data Management Scheme receives read requests for file XXX (box 700). One of the tasks performed by the Controller of the Data Management Scheme is to keep track of the location of each stored file, and its multiple ways to be locally recovered. Note that a typical file is composed of several blocks, hence any read request contains several simultaneous block reads. In the case that some of the blocks are unavailable or are requested simultaneously by several applications, the Controller can perform local recovery of the desired blocks in order to fulfill the read requests. thereby improving the overall performances of the system.

If the number of applications requesting to read the file is greater than one (an affirmative outcome at box 701), the Controller of Data Management Scheme performs a local recovery of the requested data. In other words, it answers the read requests using multiple recovering sets of the data (box 702). If the number of applications requesting to read the file equals to one (a negative outcome at box 701), the Controller of Data Management Scheme answers the read request using the original copy of the data (box 703).

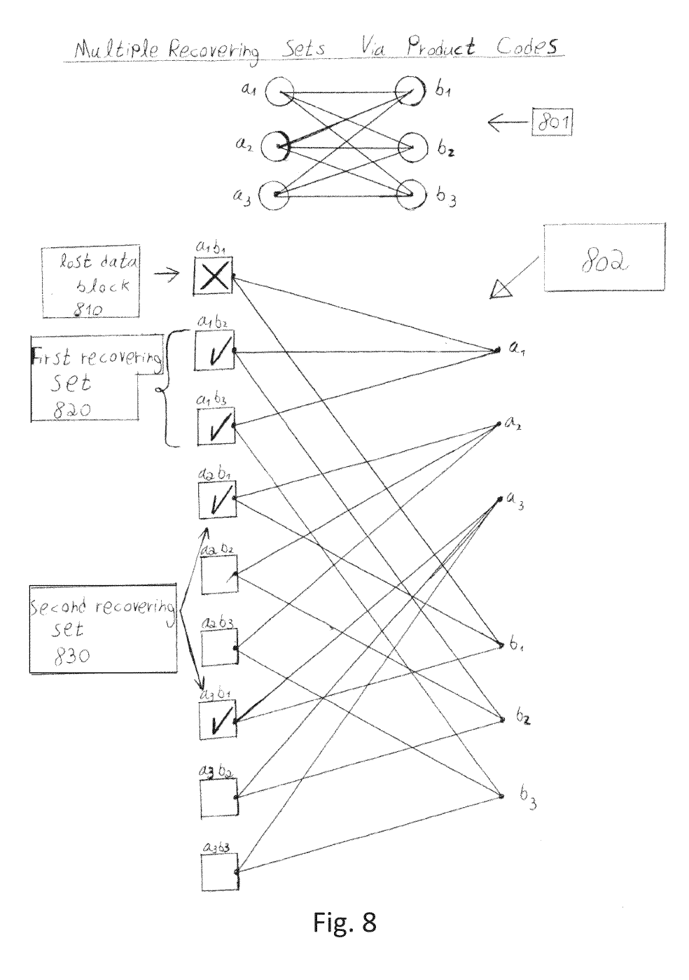

FIG. 8 illustrates an exemplary construction of a code with Multiple Disjoint Recovering Sets via Product Codes. The code in the example has two disjoint recovering sets. The symbols a₁,a₂,a₃ and b₁,b₂,b₃ in 801 represent the blocks of the first and the second codeword of a Locally Recoverable Code of length 3, respectively. These blocks form the vertices of the complete bipartite graph in 801. Each edge of the 3×3=9 edges of the graph represents a block in the final encoding of length 9. The value of the block that corresponds to the edge (aᵢ,bⱼ) in the graph is the result of the multiplication aᵢ×bⱼ, where the product is calculated over the appropriate finite field. 802 provides another representation of the graph in 801, together with an example of a lost data block (box 810). The 6 vertices on the right-hand side a₁,a₂,a₃,b₁,b₂,b₃ represent the original 6 blocks from 801. Each vertex of the 9 vertices on the left represents an edge from the graph in 801 (which represents a block in the final encoding). The value of each block is showed above the vertex. For instance, box 810 shows a lost block whose value equals to a₁b₁. Each data block on the left is connected to the corresponding blocks that it is equal to their product. For example the vertex a₁b₁ on the left is connected to the vertices a₁ and b₁ on the right. The lost block has two disjoint recovering sets as indicated by boxes 820 and 830. The first recovering set (box 820) is the set of data blocks that were also generated by the block a₁, namely blocks a₁b₂ and a₁b₃. Similarly, the second recovering set is the set of blocks that were generated by the block b₁, namely blocks a₂b₁ and a₃b₁. The lost block a₁b₁ can be recovered independently from each of these sets of data blocks.

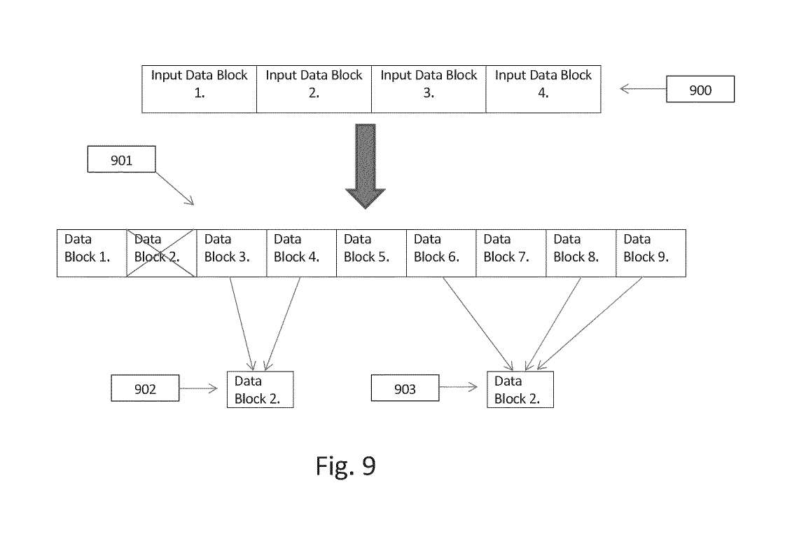

FIG. 9 illustrates an exemplary construction of a code with Multiple Disjoint Recovering Sets via Algebraic LRC codes. For the input of 4 input Data Blocks to be stored (box 900), the Controller of Data Management produces 9 data Blocks of an LRC code with two disjoint recovering sets using the algebraic LRC code method (box 901). By the properties of this method, each of the 9 data Blocks can be recovered independently in two distinct ways, by accessing one of its 2 disjoint recovering sets of size 2 and 3 respectively. For instance, assume that Data Block 2 was erased. Using Data Block 3, and Data Block 4 one can recover the erased Data Block 2 (box 902). Similarly, Using Data Block 6, Data Block 8, and Data Block 9, one can recover the erased Data Block 2 (box 903).

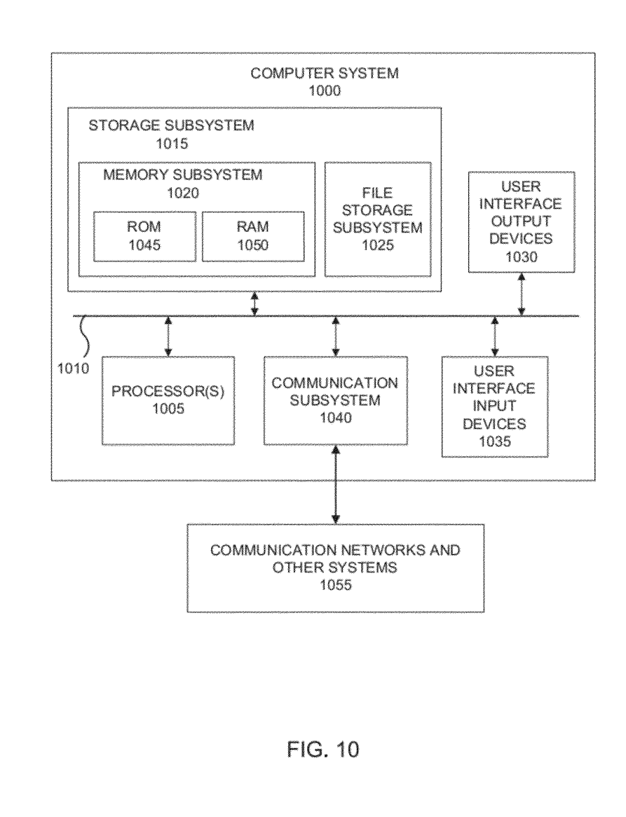

FIG. 10 illustrates a computer system such as utilized as either or both of the Controller of Data Management Scheme and host computer of FIG. 3.

The operations described above for operating the storage devices, for reading data from the storage devices, for writing data to the storage devices, and for recovering the failed storage devices and lost data, can be carried out by the operations depicted in FIG. 4, which can be performed by the controller application 303 and associated components of the Controller of Data Management Scheme 318 illustrated in FIG. 3. The controller application may be installed in a variety of computer devices that control and manage operations of an associated storage devices. For example, in an implementation of the coding scheme described herein within a single controller device, all the components of the Controller of Data Management Scheme 318 depicted in FIG. 3 can be contained within firmware of a controller device that communicates with a host computer and storage nodes (servers).

The processing components such as the controller application 303 and host interface 302 and node interface 303 can be implemented in the form of control logic in software or hardware or a combination of both, and may comprise processors that execute software program instructions from program memory, or as firmware, or the like. The host computer 301 may comprise a conventional computer apparatus. A conventional computer apparatus also may carry out the operations of FIG. 4. For example, all the components of the Controller of Data Management Scheme can be provided by applications that are installed on the computer system illustrated in FIG. 10.

FIG. 10 is a block diagram of a computer apparatus 1000 sufficient to perform as a host computer and a RAID controller, and sufficient to perform the operations of FIG. 4.

FIG. 10 is a block diagram of a computer system 1000 that may incorporate embodiments of the present disclosure and perform the operations described herein. The computer system 1000 typically includes one or more processors 1005, a system bus 1010, storage subsystem 1015 that includes a memory subsystem 1020 and a file storage subsystem 1025, user interface output devices 1030, user interface input devices 1035, a communications subsystem 1040, and the like.

In various embodiments, the computer system 1000 typically includes conventional computer components such as the one or more processors 1005. The file storage subsystem 1025 can include a variety of memory storage devices, such as a read only memory (ROM) 1045 and random access memory (RAM) 1050 in the memory subsystem 1020, and direct access storage devices such as disk drives.

The user interface output devices 1030 can comprise a variety of devices including but not limited to a flat panel displays, touchscreens, indicator lights, audio devices, force feedback devices, and the like. The user interface input devices 1035 can comprise a variety of devices including but not limited to a computer mouse, trackball, trackpad, joystick, wireless remote, drawing tablet, voice command system, eye tracking system, and the like. The user interface input devices 1035 typically allow a user to select objects, icons, text and the like that appear on the user interface output devices 1030 via a command such as a click of a button or the like.

Embodiments of the communication subsystem 1040 typically include, but are not limited to, an Ethernet card, a modem (telephone, satellite, cable, ISDN), (asynchronous) digital subscriber line (DSL) unit, FireWire (IEEE 1394) interface, USB interface, and the like. For example, the communications subsystem 1040 may be coupled to communications networks and other external systems 1055 (e.g., a network such as a LAN or the Internet), to a FireWire bus, or the like. In other embodiments, the communications subsystem 1040 may be physically integrated on the motherboard of the computer system 1000, may be a software program, such as soft DSL, or the like.

The RAM 1050 and the file storage subsystem 1025 are examples of tangible media configured to store data such as RAID configuration data, codewords, and program instructions to perform the operations described herein when executed by the one or more processors, including executable computer code, human readable code, or the like. Other types of tangible media include but are not limited to program product media such as floppy disks, removable hard disks, optical storage media such as CDs, DVDs, and bar code media, semiconductor memories such as flash memories, read-only-memories (ROMs), battery-backed volatile memories, networked storage devices, and the like. The file storage subsystem 1025 includes reader subsystems that can transfer data from the program product media to the storage subsystem 1015 for operation and execution by the processors 1005. The computer system 1000 may also include software that enables communications over a network (e.g., the communications network 1055) such as the DNS, TCP/IP, UDP/IP, and HTTP/HTTPS protocols, and the like. In alternative embodiments, other communications software and transfer protocols may also be used, for example IPX, or the like.

It will be readily apparent to one of ordinary skill in the art that many other hardware and software configurations are suitable for use with the present disclosure. For example, the computer system 1000 may be a desktop, portable, rack-mounted, or tablet configuration. Additionally, the computer system 1000 may be a series of networked computers. Further, a variety of microprocessors are contemplated and are suitable for the one or more processors 1005, such as microprocessors from Intel Corporation of Santa Clara, Calif., USA; microprocessors from Advanced Micro Devices, Inc. of Sunnyvale, Calif., USA; and the like. Further, a variety of operating systems are contemplated and are suitable, such as WINDOWS. XP, WINDOWS 7, or the like from Microsoft Corporation of Redmond, Wash., USA, SOLARIS from Sun Microsystems, Inc. of Santa Clara, Calif., USA, various Linux and UNIX distributions, and the like, and Hadoop Distributed File System. In still other embodiments, the techniques described above may be implemented upon a chip or an auxiliary processing board (e.g., a programmable logic device or graphics processor unit).

The present disclosure can be implemented in the form of control logic in software or hardware or a combination of both. The control logic may be stored in an information storage medium as a plurality of instructions adapted to direct an information-processing device to perform a set of steps disclosed in embodiments of the present disclosure. Based on the disclosure and teachings provided herein, a person of ordinary skill in the art will appreciate other ways and/or methods to implement the present disclosure.

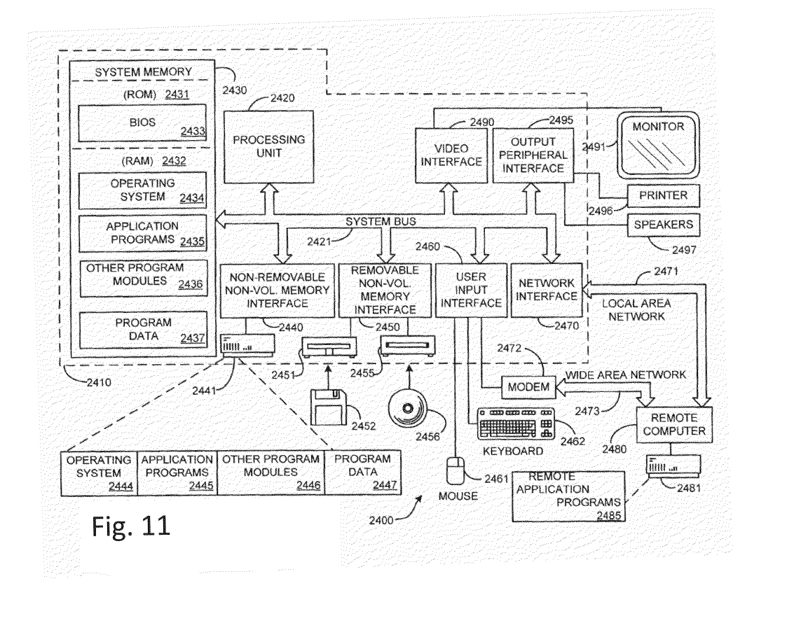

FIG. 11 illustrates an example of a suitable computing system environment in which the Locally Recoverable Coding (LRC) method can be implemented.

### DETAILED DESCRIPTION OF THE INVENTION

The contents of this Detailed Description are organized according to the following headings:

Overview

Introduction

Preliminaries on LRC codes

Code Construction

LRC codes with multiple recovering sets

Generalizations of the Main Construction

Overview

The proposed method of data recovery can be implemented on hardware such as a distributed storage system or another application designed to handling large volumes of data that cannot afford data loss and therefore rely on encoding for guaranteeing data recovery.

Other implementations using the proposed method of data recovery not explicitly mentioned are alternatively conceivable. The proposed method encodes data blocks to guarantee that a lost or corrupted block can be recovered by accessing non-corrupted data at other locations. The recovery procedure relies on accessing a small amount of data and improves the performance of existing systems by reducing the access load in the network and by reducing the energy cost, cooling cost of the data storage system, the amount of space needed for data storage, and increasing the lifespan of hardware components of the system.

The proposed method is useful in data storage and transmission systems used by various industries that rely on storing or communicating large volumes of data and information for the purposes of analysis or sharing, including but not limited to utilities wherein user energy usages are monitored, financial companies, banks and financial institutions, scientific organizations performing large-scale monitoring, image, video and data processing, collecting data for statistical purposes, biological and bioinformatics research, media industries that use or rely on collecting and storing user data and information for sharing and analysis, publishing industries, and military and law enforcement applications that rely on storing or analysing large amounts of data.

Introduction

A code over some alphabet is called locally recoverable (LRC) if every symbol in the encoding is a function of a small number (at most r) other symbols. We present a family of LRC codes that attain the maximum possible value of the distance for a given locality parameter and code cardinality. The codes can be constructed over a finite field alphabet of any size that exceeds the code length. The codewords are obtained as evaluations of specially constructed polynomials over a finite field. The recovery procedure is performed by polynomial interpolation over r points. We also construct codes with several disjoint recovering sets for every symbol, enabling simultaneous recovery at several locations by accessing different parts of the codeword.

Distributed and cloud storage systems have reached such a massive scale that recovery from several failures is now part of regular operation of the system rather than a rare exception. In addition, storage systems have to provide high data availability to ensure high performance. In order to address these requirements, redundancy and data encoding must be introduced into the system. The simplest and most widespread technique used for data recovery is replication, under which several copies of each data fragment are written to distinct physical storage nodes. However, this solution entails large storage overhead and has therefore become inadequate for modern systems supporting the “Big Data” environment. Therefore, more advanced coding techniques that provide comparable resiliency against failures at the expense of a significantly smaller storage overhead, are implemented. For example, Facebook uses the (14,10) Reed-Solomon code, which requires only 40% overhead compared to the 200% overhead associated with threefold replication.

Although today's storage systems are resilient to several concurrent node failures, in order to provide enough data reliability, by far the most common scenario is a failure of a single node. Hence, a storage system should be designed to efficiently repair such scenarios. The repair efficiency of a single node failure in the system can be quantified under different metrics, where each metric is relevant for different storage systems and applications. More precisely, in the literature, a great body of work has considered the repair problem under three metrics: i) the number of bits communicated in the network, i.e., the repair-bandwidth [6], [23], [25], [27], [4], [19] ii) the number of bits read, the disk-I/O [13], [27], and iii) repair locality, i.e., the number of nodes that participate in the repair process [9, 16, 20, 26, 24]. The fundamental limits of these metrics are yet to be fully understood. In this work, we focus on the former metric, namely the repair locality.

More formally, a Locally Recoverable Code (LRC code) of length n is a code that produces an n-symbol codeword from k data symbols, and for any symbol in the codeword, there exist at most r other symbols, such that the value of the symbol can be recovered from them. We denote such code by (n,k,r) LRC code. For LRC codes, if a symbol is lost due to a node failure, its value can be recovered by accessing the value of at most r other symbols. For example, a code of length 2k in which each coordinate is repeated twice, is an LRC code with locality r=1. Generally the locality parameter satisfies 1≧r≧k because the entire codeword can be found by accessing k other symbols. Another example is given by an (n,k) maximum distance separable, or MDS codes. In this case the locality is r=k, and not less than that, which is the largest possible value. Observe that MDS codes can recover the largest possible number of erased symbols among all (n,k) codes, but they are far from optimal in terms of locality, i.e., for correcting a single symbol erasure. Yet another simple example is provided by regular LDPC codes with r+1 non zeros in every check equation, meaning that any single symbol of the codeword is a linear combination of some other r symbols.

Codes that have good locality properties were initially studied in [10], [11], although the second of these papers considered a slightly different definition of locality, whereby a code is said to have information locality r if the value of any of its information symbols can be recovered by accessing at most r other codeword symbols. Codes with information locality property were also studied in [9]. A natural question to ask is as follows: given an (n,k,r) LRC code C, what is best possible minimum distance d(C)? A bound on d(C) as a function of n, k and r was proved in [9] by extending the arguments in the proof of the classical Singleton bound on codes (see Theorem 3.2 below). Using a probabilistic argument, [9] showed that this bound is tight over a large enough finite field. Therefore, an (n,k,r) LRC code that achieves the bound of [9] with equality is called an optimal LRC code. The Singleton-type bound of [9] does not take into account the cardinality of the code alphabet q. Augmenting this result, a recent work [4] established a bound on the distance of LRC codes that depends on q, sometimes yielding better results. Another perspective of the limits for LRC codes was addressed in [15] which showed that locality cannot be too small if the codes are required to attain capacity of, say, the binary symmetric channel.

There are two optimal constructions of LRC codes known in the literature. Namely, [24] proposed a two-level construction based on the well-known Gabidulin codes combined with a single parity-check (r+1,r) code. Another construction [26] used two layers of MDS codes, a Reed-Solomon code and a special (r+1,r) MDS code. A common shortcoming of these constructions relates to the size of the code alphabet which in both papers is an exponential function of the code length, complicating the implementation. The only known constructions of optimal LRC over alphabet size comparable to code's length are for locality r=1,k, and recently paper [21] constructed such code for a specific code's length

$$n = ⌈ \frac{k}{r} ⌉ ( r + 1 ) .$$

To overcome the shortcoming, this disclosure presents a construction that relies on the alphabet of cardinality comparable to the code length n.

Recently [17] constructed LRC codes with several disjoint repair alternatives using partial geometries. [22] presented a new framework for designing distributed storage codes that are efficient in data-read and download required during repair. In [12] codes that combine two of the metrics were constructed, i.e., LRC codes that seek to minimize the repair bandwidth during repair of a failed node.

A similar notion of locality was introduced in [3], called maximally recoverable codes with locality. The symbols in such codes can be grouped into disjoint sets of size r+1 that form a simple parity check code. Moreover, puncturing in each codeword one coordinate from each group yields to an MDS code. Hence the value of each symbol in such codes can be recovered by a simple parity check sum of r other symbols.

The main construction of optimal (n,k,r) LRC codes over the finite field F_{q}, q≦n is presented in Section 4. There are several versions of the construction that are discussed in detail, together with some examples of short optimal LRC codes. We also observe that the encoding can be made systematic, which may be beneficial in implementations. In Section 5 we give two constructions of LRC codes with multiple disjoint recovering sets for each symbol, which enables simultaneous recovery from different portions of the encoding. In Section 6 we discuss several extensions of the main construction, in particular, pointing out that the simplifying assumptions made earlier in the disclosure can be removed with only small changes in the resulting codes.

Throughout the disclosure C denotes a code over a finite field F_{q}. The triple of parameters (n,k,r) refers to a code of length n, cardinality q^{k} and locality r. The finite field is also denoted by F if its cardinality is understood or does not matter. We also use the notation [n]:={1, . . . , n}. A restriction C_{I} of the code C to a subset of coordinates I⊂[n] is the code obtained by removing from each vector the coordinates outside I.

Preliminaries on LRC Codes

We say that a code C⊂F_{q}ⁿ has locality r if every symbol of the codeword xεC can be recovered from a subset of r other symbols of x (i.e., is a function of some other r symbols xᵢ_{₁}, Xᵢ_{₂}, Xᵢ_{ᵣ}). In other words, this means that, given xεC, iε[n], there exists a subset of coordinates Iᵢ⊂[n]\i,|Iᵢ|≦r such that the restriction of C to the coordinates in Iᵢ enables one to find the value of xᵢ. The subset Iᵢ is called a recovering set for the symbol xᵢ.

The formal definition is as follows. Given aεF_{q} consider the sets of codewords

C(i,a)={xεC:xᵢ=a},iε[n].

The code C is said to have locality r if for every iε[n] there exists a subset Iᵢ⊂[n]\i, |Iᵢ|≦r such that the restrictions of the sets C(i,a) to the coordinates in Iᵢ for different a are disjoint:

C_{I}_{ᵢ}(i,a)∩C_{I}_{ᵢ}(i,a′)=Ø,a≠a′.

The code C_{I}_{ᵢ}_{∪[i]} is called a local code of the code C. In the constructions of LRC codes presented in the literature the set of coordinates of the (n,k,r) LRC code is usually partitioned into (r+1,r) local MDS codes that define the recovering sets of the symbols.

Two desirable features of codes is high minimum distance and high rate. We begin with a short proof of two bounds on these features in an LRC code. The bound on the distance appeared also in [9, 18] using different techniques, and is included here for completeness. We will use the following theorem which is a slight modification of the well known Turan's Theorem on the size of a maximal independent set in a graph.

Theorem 3.1

Let G be a directed graph on n vertices, then there exists an induced directed acyclic subgraph of G on at least

$$\frac{n}{1 + \frac{{\sum }_{i} {d}_{i}^{out}}{n}}$$

vertices. Where dᵢ^{out} is the outgoing degree of vertex i.

Proof

We follow the proof of the undirected version of this result that appears in [1, pp. 95-96]. Choose uniformly a total ordering π on the set of vertices [n], and let U⊂[n] be a subset of vertices defined as follows: A vertex i belongs to U iff for any outgoing edge from i to some vertex j, π(i)<π(j). The induced subgraph of G on U is a directed acyclic graph, since if i₁, . . . iₘ in is a cycle where iⱼεU then i

π(i₁)<π(i₂)< . . . <π(iₘ)<π(i₁),

and we get a contradiction. Let X=|U| be the size of U, and let Xᵢ be the indicator random variable for iεU. Clearly X=ΣᵢXᵢ and for each i

$$E ( {X}_{i} ) = P ( i ∈ U ) = \frac{{d}_{i}^{out} !}{( 1 + {d}_{i}^{out} ) !} = \frac{1}{1 + {d}_{i}^{out}} .$$

Using the inequality between the arithmetic mean and the harmonic mean, we obtain

$$E ( X ) = {\sum }_{i} \frac{1}{1 + {d}_{i}^{out}} \geq \frac{n}{1 + \frac{{\sum }_{i} {d}_{i}^{out}}{n}} .$$

Therefore there exists a specific ordering π with

$$\vert U \vert \geq \frac{n}{1 + \frac{{\sum }_{i} {d}_{i}^{out}}{n}} .$$

Theorem 3.2

Let C be an (n,k,r) LRC code of cardinality q^{k} over an alphabet of size q, then the rate of C satisfies

$$\frac{k}{n} \leq \frac{r}{r + 1} . \qquad ( 1 )$$

The minimum distance of C satisfies

$$d \leq n - k - ⌈ \frac{k}{r} ⌉ + 2. \qquad ( 2 )$$

A code that achieves the bound on the distance with equality will be called an optimal LRC code.

Proof.

Consider the following directed graph G on the set of coordinates [n] of C, where there is a directed edge from i to j iff jεIᵢ. Since the code has locality r, the outgoing degree of each vertex is at most r, and by Theorem 3.1 G contains an induced directed acyclic subgraph G_{U} on the set of vertices U, where

$$\vert U \vert \geq \frac{n}{1 + r} . \qquad ( 3 )$$

Let i be a coordinate in G_{U} without outgoing edges, then it is clear that coordinate i is a function of the coordinates [n] \U. Continuing with this argument, consider the induced subgraph of G on U\i. Clearly it is also a directed acyclic graph. Let i′ be another coordinate without outgoing edges in G_{U\i}, hence coordinate i′ is function of the coordinates [n]\U. Iterating this argument we conclude that any coordinate iεU is a function of the coordinates [n]\U. This means that we have found at least

$$\vert U \vert \geq \frac{n}{r + 1}$$

coordinates that are redundant. Therefore, the number of information coordinates k is at most rn/(r+1), as claimed.

For the second part recall the definition of the minimum distance of the code

$$d = n - {max}_{I ⊆ [ n ]} \{ \vert I \vert : \vert {C}_{I} \vert < {q}^{k} \} , \qquad ( 4 )$$

Where C_{I} is the restriction of the code C to the coordinates in I. From the first part and by (3) let U′⊂U of size

$$\vert {U}^{′} \vert = ⌊ \frac{k - 1}{r} ⌋ .$$

Clearly the induced subgraph of G on U′ is a directed acyclic graph. Let N be the set of coordinates in [n]\U′ that have at least one incoming edge from a coordinate in U′. Note that

$$\vert N \vert \leq r \vert {U}^{′} \vert = r ⌊ \frac{k - 1}{r} ⌋ \leq k - 1 ,$$

and that each coordinate in U′ is a function of the coordinates in N. Add to N arbitrary k−1−|N| coordinates from the set [n]\(N∪U′) to obtain the set N′ of size k−1. Hence

|C_{N′∪U′}|=|C_{N′},|≦q^{k-1},

and

$$\vert {N}^{′} ⋃ {U}^{′} \vert = k - 1 + ⌊ \frac{k - 1}{r} ⌋ .$$

Then we conclude that

$${max}_{I ⊆ [ n ]} \{ \vert I \vert : \vert {C}_{I} \vert < {q}^{k} \} \geq k - 1 + ⌊ \frac{k - 1}{r} ⌋ ,$$

and, using (4),

$$d \leq n - ( k - 1 + ⌊ \frac{k - 1}{r} ⌋ ) = n - k - ⌈ \frac{k}{r} ⌉ + 2.$$

It is clear that in any code, each symbol has locality at most k, so r always satisfies 1≦r≦k. Upon letting r=k, (2) becomes the well-known Singleton bound,

d≦n−k+1, (5)

So optimal LRC codes are precisely MDS codes, e.g. RS codes. On the other hand, if r=1, the bound (2) becomes

$$d \leq n - 2 k + 2 = 2 ( \frac{n}{2} - k + 1 ) .$$

Replicating each symbol twice in an (n/2,k) MDS code, we obtain an optimal LRC with locality r=1.

4. Code Construction

In this section we construct optimal linear (n,k,r) LRC codes over a finite field alphabet of size q, where q is any prime power greater or equal to n. In the first version of the construction we assume that k is divisible by r (this restriction will be removed later in this section). Throughout this section we also assume that n is divisible by r+1 (this restriction can also be lifted, see Sect. 6.1).

4.1 General Construction

We begin with a general method of constructing linear codes with the locality property. Later, we will show that some of these codes have optimal minimal distance. The codes are constructed as evaluations of polynomials, in line with many other algebraic code constructions. Unlike the classical Reed-Solomon codes, the new codes will be evaluated at a specially chosen set of points of the field F_{q}, q≧n. A key ingredient of the construction is a polynomial g(x)εF_{q}[x] that satisfies the following conditions:
a. The degree of g is r+1,
b. There exists a partition

$$A = \{ {A}_{1} , … , {A}_{\frac{n}{r + 1}} \}$$

or a set A⊂F_{q} of size n into sets of size r+1, such that g is constant on each set Aᵢ in the partition. Namely for all i=1, . . . , n/(r+1), and any α,βεAᵢ,
c. g(α)=g(β).

A polynomial that satisfies these conditions will be called good. The code construction presented below relies on the existence of good polynomials.

Construction 1 ((n,k,r) LRC Codes)

Let n≦q be the target code length. Let A⊂F_{q}, |A|=n and let g(x) be a good polynomial for the partition A of the set A. To find the codeword for a message vector aεF_{q}^{k} write it as

$$a = ( {a}_{ij} , i = 0 , ⋯ , r - 1 ; j = 0 , ⋯ , \frac{k}{r} - 1 ) .$$

Define the encoding polynomial

$$\begin{matrix}{f}_{a} ( x ) = {\sum }_{i = 0}^{r - 1} {f}_{i} ( x ) {x}^{i} , & ( 6 ) \\ Where {f}_{i} ( x ) = {\sum }_{j = 0}^{\frac{k}{r} - 1} {a}_{ij} {g ( x )}^{j} , i = 0 , ⋯ , r - 1 & ( 7 )\end{matrix}$$

We call the fᵢ's the coefficient polynomials. The codeword for a is found as the evaluation vector of fₐ at all the points of A. In other words, the (n,k,r) LRC code C is defined as the set of n-dimensional vectors

C={(fₐ(α),αεA):aεF_{q}^{k}}. (8)

We call the elements of the set A locations and the elements of the vector (fₐ(α)) symbols of the codeword.

The local recovery is accomplished as follows.

Recovery of the Erased Symbol:

Suppose that the erased symbol corresponds to the location αεAⱼ, where Aⱼ is one of the sets in the partition A. Let (c_{β}, βεAⱼ\α) denote the remaining r symbols in the set Aⱼ. To find the value c_{α}=fₐ(α), find the unique polynomial δ(x) of degree less than r such that δ(β)=c_{β} for all βεAⱼ\α, i.e,

$$δ ( x ) = {\sum }_{β ∈ {A}_{j} \backslash α} {c}_{β} {\prod }_{{β}^{′} ∈ {A}_{j} \backslash \{ α , β \}} \frac{x - {β}^{′}}{β - {β}^{′}} \qquad ( 9 )$$

and set c_{α}=δ(α). We call δ(x) the decoding polynomial for the symbol c_{α}. Thus, to find one erased symbol, we need to perform polynomial interpolation from r known symbols in its recovery set. This recovery procedure underlies all the constructions in this disclosure.

In the next theorem we prove that the codes constructed above are optimal with respect to the bound (2), and justify the validity of the recovery procedure.

Theorem 4.1

The linear code C defined in (8) has dimension k and is an optimal (n,k,r) LRC code, namely its minimum distance meets the bound (2) with equality.

Proof.

By (6), (7) the degree of the polynomial fₐ(x) is at most

$$( \frac{k}{r} - 1 ) ( r + 1 ) + r - 1 = k + \frac{k}{r} - 2 \leq n - 2 ,$$

Where the last inequality follows from Proposition 1 on the rate of LRC codes.

Therefore, since the encoding is linear, the distance satisfies

$$d ( C ) \geq n - {max}_{{f}_{a} , a ∈ {F}_{q}^{k}} deg ( {f}_{a} ) = n - k - \frac{k}{r} + 2$$

Which together with (2) completes the proof.

Let us prove the locality property. Let Aⱼ be a member of the partition A and assume that the lost symbol of the codeword equals c_{α}=fₐ(α), where αεAⱼ is a field element.

Define the decoding polynomial

$$δ ( x ) = {\sum }_{i = 0}^{r - 1} {f}_{i} ( α ) {x}^{i} , \qquad ( 10 )$$

Where the fᵢ(x) are the coefficient polynomials (7). We will show that this polynomial is the exact same polynomial in (9). Each fᵢ(x) is a linear combination of powers of g, therefore it is also constant on the set Aⱼ, i.e., for any βεAⱼ and any coefficient polynomial fᵢ, i=1, . . . , r−1

fᵢ(β)=fᵢ(α). (11)

Hence by (10) and (11), for any β in Aⱼ

$$δ ( β ) = {\sum }_{i = 0}^{r - 1} {f}_{i} ( α ) {β}^{i} = {\sum }_{i = 0}^{r - 1} {f}_{i} ( β ) {β}^{i} = {f}_{a} ( β ) .$$

In other words, the values of the encoding polynomial fₐ(x) and the decoding polynomial δ(x) on the locations of Aⱼ coincide. Since δ(x) is of degree at most r−1, it can be interpolated from the r symbols c_{β}, βεAⱼ\α, cf. Eq. (9). Once δ(x) is computed, we find the lost symbol as δ(α). To conclude, the lost symbol c_{α} can be recovered by accessing r other symbols of the codeword.

As a consequence of this proof, we note that the polynomial δ(x) satisfies the condition δ(α)=fₐ(α) for all αεAⱼ, i.e., it is determined by the index j of the recovery set Aⱼ. In other words, the decoding polynomial δ(x) is the same for any two symbols α₁,α₂εAⱼ.

### Example 1

In this example we construct an optimal (n=9, k=4, r=2) LRC code over the field F_{q}. Since we need 9 distinct evaluation points of the field, we must choose q≧9. We define the code C over F₁₃.

The difficulty of using Construction 1 is in constructing a good polynomial g of degree r+1=3 that is constant on 3 disjoint sets of size 3. In this example we offer little motivation in constructing g(x) but later we will give a systematic way of constructing them.

Let the partition A be as follows:

A={A₁={1,3,9},A₂={2,6,5},A₃={4,12,10}},

and note that the polynomial g(x)=x³ is constant on the sets Aᵢ. Let a=(a_{0,0},a_{0,1},a_{1,0},a_{1,1}) be the information vector of length k=4 over F₁₃ and define the encoding polynomial by (6), (7)

$$\begin{matrix}{f}_{a} ( x ) = ( {a}_{0 , 0} + {a}_{0 , 1} g ( x ) ) + x ( {a}_{1 , 0} + {a}_{1 , 1} g ( x ) ) \\ = ( {a}_{0 , 0} + {a}_{0 , 1} {x}^{3} ) + x ( {a}_{1 , 0} + {a}_{1 , 1} {x}^{3} ) \\ = {a}_{0 , 0} + {a}_{1 , 0} x + {a}_{0 , 1} {x}^{3} + {a}_{1 , 1} {x}^{4} .\end{matrix}$$

The codeword c that corresponds to a is found as the evaluation of the polynomial fₐ at all the points of the sets of the partition A: c=(fₐ(α),αε∪ᵢ₌₁³Aᵢ). Since deg fₐ≦4, the minimum distance is at least 5, and so d=5 by (2). For instance, assume that a=(1,1,1,1), then the codeword is found to be

(fₐ(1),fₐ(3),fₐ(9),fₐ(2),fₐ(6),fₐ(5),fₐ(4),fₐ(12),fₐ(10))=(4,8,7,1,11,2,0,0,0)

Suppose that the value fₐ(1) is erased. By our construction, it can be recovered by accessing 2 other codeword symbols, namely, the symbols at locations corresponding to 3 and 9. Using (9) we find δ(x)=2x+2 and compute δ(1)=4, which is the required value.

Remarks:

1. Construction 1 is a direct extension of the classical Reed-Solomon (RS) codes in that both are evaluations of some polynomials defined by the message vector. Our construction also reduces to Reed-Solomon codes if r is taken to be k. Note that if r=k then each coefficient polynomial is a constant (7), and therefore the code construction does not require a good polynomial. For the same reason, the set A for RS codes can be an arbitrary subset of F_{q}, while the locality condition for r<k imposes a restriction on the choice of the locations. It was found that the suggested methods illustrated in this application are applicable to cases where r is smaller than k—and thus a failed symbol can be reconstructed from a smaller (r) number of non-failed symbols (in relation to the k symbols required for RS codes) which is very beneficial. For example less read operations are required.

2. Note that if the coordinates of the vector a are indexed as a=(a₀, . . . , aₖ₋₁) then the encoding polynomial in (6) can be also written as

$${f}_{a} ( x ) = {\sum }_{{m = 0}_{m \neq r mod ( r + 1 )}}^{k + \frac{k}{r} - 2} {a}_{m} {g ( x )}^{⌊ \frac{m}{r + 1} ⌋} {x}^{m mod ( r + 1 )} . \qquad ( 12 )$$

To see this, put in (7) aₘ=aᵢ₊ⱼ₍ᵣ₊ᵢ₎, i=0, . . . , r−1; j=0, . . . , k/r−1, and observe that

$$⌊ \frac{k + \frac{k}{r} - 2}{r + 1} ⌋ = \frac{k}{r} - 1 ,$$

and that there are k/r−1 numbers in the set {0, 1, . . . , k+(k/r)−2} equal to r modulo r+1.

3. In Construction 1 we assumed that r divides k; however, this constraint can be easily lifted. Indeed, suppose that r/k and define the coefficient polynomial fᵢ in (7) as follows:

$${f}_{i} ( x ) = {\sum }_{j = 0}^{j ( k , r , i )} {a}_{ij} {g ( x )}^{j} , \\ i = 0 , 1 , … , t - 1 , \\ Where$$

$$j ( k , r , i ) = \{ \begin{matrix}⌊ \frac{k}{r} ⌋ & i < k mod r \\ ⌊ \frac{k}{r} ⌋ - 1 & i \geq k mod r\end{matrix} .$$

It is easy to see that the r coefficient polynomials are defined by the k information symbols, and the resulting encoding polynomial fₐ has degree at most k+┌k/r┐−2. The remaining parts of the construction are unchanged.

4.2 Constructing Optimal LRC Codes Using Algebraic Structure of the Field

The main component of Construction 1 is finding a good polynomial g(x) together with the corresponding partition of the subset A of the field. In this section we show how to construct g(x) using the multiplicative and additive groups of F_{q}.

The multiplicative group F_{q}* is cyclic, and the additive group F_{q}⁺ is isomorphic to a direct product of l copies of the additive group Zₚ⁺, where q=p^{l} and p is the characteristic of the field. The following obvious proposition constructs a good polynomial from any subgroup of F_{q}* or F_{q}⁺.

Proposition 4.2

Let H be a subgroup of F_{q}* or F_{q}⁺. The annihilator polynomial of the subgroup

$$g ( x ) = {\prod }_{h ∈ H} ( x - h ) . \qquad ( 13 )$$

Is constant on each coset of H.

Proof.

Assume that H is a multiplicative subgroup and let a,a h̅ be two elements of the coset aH, where h̅εH, then

$$g ( a \overline{h} ) = {\prod }_{h ∈ H} ( a \overline{h} - h ) = {\overline{h}}^{\vert H \vert} {\prod }_{h ∈ H} ( a - h {\overline{h}}^{- 1} ) = {\prod }_{h ∈ H} ( a - h ) = g ( a ) .$$

The proof for additive subgroups is completely analogous.

Thus annihilators of subgroups form a class of good polynomials that can be used to construct optimal codes. The partition A is a union of cosets of H, so the code length n can be any multiple of r+1 satisfying n≦q≦1 (or n≦q in the case of the additive group). Since the size of the subgroup divides the size of the group we get that qmod(r+1) is 1 (or 0).

The parameters of LRC codes constructed using subgroups are naturally restricted by the possible size of the subgroups. Note that Example 1 is constructed using the multiplicative subgroup H={1,3,9} of the field F₁₃, and the annihilator is g(x)=x³−1. In the example we used another good polynomial, g(x)=x³.

### Example 2

In this example we construct an optimal (12,6,3) LRC code with minimum distance d=6 over F₁₃. Note that 5 is an (r+1)=4-th root of unity modulo 13, therefore the polynomial g(x)=x⁴ is constant on the cosets of the cyclic group H={1,5,12,8} generated by 5. Note that the polynomial g constructed in Proposition 4.2 is in fact g(x)=x⁴−1, while we used the polynomial g(x)=x⁴. Since the polynomials 1,x⁴−1 span the same subspace as the polynomials 1,x⁴, the resulting codes are equivalent.

The group H gives rise to the partition of F₁₃*

A={A₁={1,5,12,8},A₂={2,10,11,3},A₃={4,7,9,6}}.

For the information vector (a₀, a₁, a₂, a₄, a₅, a₆) define the encoding polynomial (12)

$${f}_{a} ( x ) = {\sum }_{{i = 0}_{i \neq 3}}^{6} {a}_{i} {x}^{i} = {f}_{0} ( x ) + {f}_{1} ( x ) x + {f}_{2} ( x ) {x}^{2}$$

With coefficient polynomials equal to

f₀(x)=a₀+a₄x⁴, f₁(x)=a₁+a₅x⁴, f₂(x)=a₂+a₆x⁴

The corresponding codeword is obtained by evaluating fₐ(x) for all the points xεF₁₃*.

### Example 3

In this example we construct an optimal LRC using the additive group of the field. Let α be a primitive element of the field F₂_{⁴} and take the additive subgroup H={x+yα:x, yεF₂}. The polynomial g(x) in (13) equals

g(x)=x(x+1)(x+α)(x+α+1)=x⁴+(α²+α+1)x²+(α²+α)x.

We will construct an optimal (12,6,3) LRC code with distance d=6. For i=0,1,2 define the coefficient polynomials

fᵢ(x)=a_{i,0}+a_{i,1}g(x),

Using the information vector a=(a_{i,j}) and i=0, 1, 2, j=0, 1. The subgroup H is of order 4, hence in order to have 12 evaluation points, we choose any 3 cosets of H out of its 4 cosets, and evaluate the encoding polynomial

fₐ(x)=f₂(x)x²+f₁(x)x+f₀(x)

At the elements of these cosets. Theorem 4.1 implies that the resulting code has the claimed properties. Comparing this code with a (12,6) MDS code, we note that both codes can be defined over F₂_{⁴}, however by reducing the minimum distance from 7 to 6 we managed to reduce the locality by a factor of two, from 6 to 3.

The additive and the multiplicative structures of the field can be combined into a more general method of constructing good polynomials. For two subsets H, G⊂F, we say that H is closed under multiplication by G, if multiplying elements of H by elements of G does not take the result outside H, i.e., if {hg:hεH, gεG}⊂H.

Theorem 4.3

Let l, s, m be integers such that l divides s, p^{l} mod m=1, and p is a prime. Let H be an additive subgroup of the field Fₚ_{^{s}} that is closed under the multiplication by the field Fₚ_{^{l}}, and let α₁, . . . , αₘ be the m-th degree roots of unity in Fₚ_{^{s}}. Then for any bεFₚ_{^{s}} the polynomial

$$g ( x ) = {\prod }_{i = 1}^{m} {\prod }_{h ∈ H} ( x + h + {α}_{i} ) . \qquad ( 14 )$$

is constant on the union of cosets of H, ∪_{1≦i≦m} H+bαᵢ, and the size of this union satisfies

$$\vert {⋃}_{1 \leq i \leq m} H + b {α}_{i} \vert = \{ \begin{matrix}\vert H \vert & if b ∈ H \\ m \vert H \vert & if b ∉ H\end{matrix} .$$

Proof.

Let h̅εH and let h̅+bαⱼ be an arbitrary element, then

$$\begin{matrix}g ( \overline{h} + b {α}_{i} ) = {\prod }_{i = 1}^{m} {\prod }_{h ∈ H} ( \overline{h} + b {α}_{j} + h + {α}_{i} ) \\ = {\prod }_{i = 1}^{m} {\prod }_{h ∈ H} ( b {α}_{j} + h + {α}_{i} ) \\ = {α}_{j}^{- m \vert H \vert} {\prod }_{i = 1}^{m} {\prod }_{h ∈ H} ( b + h {α}_{j}^{- 1} + {α}_{i} {α}_{j}^{- 1} ) \\ = {\prod }_{i = 1}^{m} {\prod }_{h ∈ H} ( b + h {α}_{j}^{- 1} + {α}_{i} ) \\ = {\prod }_{i = 1}^{m} {\prod }_{h ∈ H} ( b + h + {α}_{i} ) \\ = g ( b ) .\end{matrix}$$

Where we have made changes of the variables and used the assumption that H is closed under multiplication by any m-th degree root of unity, since it is closed multiplication by Fₚ_{^{l}}. For the last part on the size of the union of the cosets, consider two distinct m-th roots of unity αᵢ, αⱼ, then

H+bαᵢ=H+bαⱼ [symbol] b(αᵢ−αⱼ)εH [symbol] bεH,

where the last step follows since αᵢ−αⱼ is a nonzero element of Fₚ_{^{l}} and H closed under multiplication by the elements of Fₚ_{^{l}}.

Remarks:

1. In order to construct a good polynomial using Theorem 4.3, one needs to find an additive subgroup H of Fₚ_{^{s}} that is closed under multiplication by Fₚ_{^{l}}. Note that since l divides s, the field Fₚ_{^{s}} can be viewed as a vector space of dimension s/l over the field Fₚ_{^{l}}. Therefore any subspace H of dimension 1≦t≦s/l is in fact an additive subgroup of the field Fₚ_{^{s}} that is closed under multiplication by Fₚ_{^{l}}, and is of size |H|=(p^{l})ₜ=p^{tl}.

2. Since the degree of the polynomial g(x) in (14) is m|H|, it is clear that it takes distinct values on different sets of the form U=∪ᵢbαᵢ. In other words, g(x) partitions Fₚ_{^{s}} into (p^{s}−|H|)/m|H| sets of size m|H| and one set of size |H|, according to the values taken on the elements of the field. Hence, over the field of size p^{s}, one can construct an optimal LRC code of length n≦p^{s} such that m|H| divides n.

Assume that one wants to construct an LRC code over a field of a specific characteristic p, e.g., p=2, then Theorem 4.3 gives a flexible method of constructing good polynomials for a large set of parameters. More specifically, Let m be an integer not divisible by p, and let l be the smallest integer such that p^{l} mod m=1 (note that l≦φ(m), where φ(·) is Euler's totient function). Then is it possible to construct a good polynomial that is constant on sets of size mp^{t} for any integer t which is a multiple of l.

### Example 4

Suppose that p=7 and the code parameters are (n=28, r=13). Hence in order to construct a code of length n=28 we can choose any two out of the three sets of size 14. Note that the dimension of the code can take any value k≦nr/(r+1)=26.

Let us summarize the constructions of good polynomials depending on the value of the parameters. Suppose that the value of the characteristic p and the size of the sets mp^{t} are fixed, where m and p are coprime, then

If t=0 we can use multiplicative subgroups of some field extension Fₚ_{^{l}} that satisfies p^{l} mod m=1;

If t>0 and m=1 we can rely on additive subgroups;

If t, m>1 and t is a multiple of l, where l is the smallest integer such that p^{l} mod m=1, we combine the additive and multiplicative structures of the field as in Theorem 4.3.

There is one case where we are not able to construct good polynomials. For example, using the technique discussed above it is not possible to construct a code with locality r=5 over any extension of the field F₂. This follows since the size of the set is r+1=5+1=3·2, hence m=3 and l=2 is the smallest integer such that 2^{l} mod 3=1, however t=1 is not a multiple of l=2. On the other hand, a simple counting argument shows that good polynomials exist also for this unresolved case if the field F_{q} is large enough.

Proposition 4.4

Let F_{q} be the finite field of size q. There exists a good polynomial of degree r+1 that is constant on at least

$$⌈ ( \begin{matrix}q \\ r + 1\end{matrix} ) {lq}^{r} ⌉$$

sets of size r+1.

Proof.

Consider the set M_{q,r}={fεF_{q}[x]: f=Πᵢ₌₁^{r+1}(x−αᵢ)}, where αᵢ, i=1, . . . , r+1 vary over all

$$( \begin{matrix}q \\ r + 1\end{matrix} )$$

possible choices of subsets of the field of size r+1. In other words, M_{p,r} is the set of all monic polynomials of degree r+1 in F_{q}[x] that also have r+1 distinct zeros in F_{q}. We say that two polynomials f(x)=x^{r+1}+Σᵢ₌₀^{r}aᵢxⁱ, g(x)εM_{q,r}, are equivalent if they differ by a constant. Clearly this is an equivalence relation on M_{q,r}, and the number of equivalence classes is at most q^{r} according to the number of choices of r-tuples of the coefficients α₁, . . . , aᵣ. Hence there exists an equivalence class of size at least

$$⌈ ( \begin{matrix}q \\ r + 1\end{matrix} ) / {q}^{r} ⌉ .$$

Let f be a representative of this class, and note that it is constant on the set of zeros of any other polynomial g from this class. We conclude that f is a good polynomial that is constant on sets of size r+1, and the number of sets is at least

$$⌈ ( \begin{matrix}q \\ r + 1\end{matrix} ) / {q}^{r} ⌉ .$$

When q is large enough, e.g., q>n(r+1)^{r}, the quantity

$$⌈ ( \begin{matrix}q \\ r + 1\end{matrix} ) / {q}^{r} ⌉$$

exceeds n/(r+1) which is the desired number of sets for the construction. For instance, taking q=2¹¹, we observe that there exists a polynomial gεF_{q}[x] of degree r+1=6 that is constant on at least 3 disjoint sets of size 6. Indeed, we find that

$$\frac{( \begin{matrix}{2}^{11} \\ 6\end{matrix} )}{{( {2}^{11} )}^{5}} \approx 2.82 .$$

Using Construction 1 and the polynomial g, we can construct an optimal LRC code over F_{q} of length n=18, locality r=5 and dimension k≦15.

4.3 A General View of the LRC Code Family

In this section we study the mapping from the set of polynomials of the form (6) to Fⁿ, generalizing the code construction presented above.

Let A⊂F, and let A be a partition of A into m sets Aᵢ. Consider the set of polynomials F_{A}[x] of degree less than |A| that are constant on the blocks of the partition:

F_{A}[x]={fεF[x]:f is constant on Aᵢ,i=1, . . . ,m;deg f<|A|}. (15)

The annihilator of A is the smallest-degree monic polynomial h such that h(a)=0 if aεA, i.e., h(x)=Π_{aεA}(x−a). Observe that the set F_{A}[x] with the usual addition and multiplication modulo h(x) becomes a commutative algebra with identity. Since the polynomials F_{A}[x] are constant on the sets of A, we write f(Aᵢ) to refer to the value of the polynomial f on the set AᵢεA. We will also use a short notation for multiplication of polynomials, writing fg instead of fg mod h.

The next proposition lists some properties of the algebra.

Proposition 4.5

Let fεF_{A}[x], be not a constant polynomial then maxᵢ|Aᵢ|≦deg(f)<|A|;

The dimension dim(F_{A}[x])=m, and the m polynomials f₁, . . . , fₘ that satisfy fᵢ(Aⱼ)=δ_{i,j} and deg(fᵢ)<|A|, form a basis (here δ_{i,j} is the Kronecker delta). Explicitly,

$${f}_{i} ( x ) = {\sum }_{a ∈ {A}_{i}}^{ } {\prod }_{b ∈ A \backslash a}^{ } \frac{x - b}{a - b} \qquad ( 16 )$$

Let α₁, . . . , αₘ be distinct nonzero elements of F, and let g be the polynomial of degree deg(g)<|A| that satisfies g(Aᵢ)=αᵢ for all i=1, . . . , m, i.e.,

$$g ( x ) = {\sum }_{i = 1}^{m} {α}_{i} {\sum }_{a ∈ {A}_{i}}^{ } {\prod }_{b ∈ A \backslash a}^{ } \frac{x - b}{a - b} .$$

Then the polynomials 1, g, . . . , g^{m-1} form a basis of F_{A}[x].

There exist m integers 0=d₀<d₁< . . . <dₘ₋₁<|A| such that the degree of each polynomial in F_{A}[x] is dᵢ for some i.

Proof.

(1) For a polynomial fεF_{A}[x], and a set AᵢεA, the polynomial f(x)−f(Aᵢ) has at least |A| zeros in F, and therefore deg(f)≧|Aᵢ|.

(2) The m polynomials f₁, . . . , fₘ defined in (16) are clearly linearly independent since if for some αᵢ's in the field

$${\sum }_{i = 1}^{m} {α}_{i} {f}_{i} ( x ) = 0 ,$$

Then for any j=1, . . . , m

$${\sum }_{i = 1}^{m} {α}_{i} {f}_{i} ( {A}_{j} ) = {\sum }_{i = 1}^{m} {α}_{i} {δ}_{i , j} = {α}_{j} = 0.$$

By definition, the polynomials f₁, . . . , fₘ span F_{A}[x].

(3) Because of part (2) it is sufficient to show that the polynomials 1, g, . . . , g^{m-1} are linearly independent. Assume that for some βⱼ's in F,

$${\sum }_{j = 1}^{m} {β}_{j} {g}^{j - 1} ( x ) = 0. \qquad ( 17 )$$

Define the m×m matrix V=(v_{i,j}) where v_{i,j}=(g^{j-1}(Aᵢ)). From (17) we conclude that V·(β₁, . . . , βₘ)^{T}=0, however V is a Vandermonde matrix defined by m distinct nonzero elements of the field, therefore it is invertible, and βᵢ=0 for all i.

(4) Let f₀, . . . , fₘ₋₁ be a basis for the algebra F_{A}[x]. W.l.o.g. we can assume that the degrees of the polynomials are all distinct, since if this is not the case, one can easily find such basis by using linear operations on the fᵢ's. For this, consider an m×|A| matrix whose rows are formed by the coefficient vectors of the polynomials fᵢ. The rows of the reduced row-echelon form of this matrix correspond to a basis of polynomials of distinct degrees. Let dᵢ=deg(fᵢ), and assume that d₀<d₁< . . . <dₘ₋₁. Since the constant polynomials are contained in the algebra, d₀=0, and the result follows.

Next we consider a special case of an algebra generated by a set A of size n, assuming that the partition satisfies |Aᵢ|=r+1 for all i.

Corollary 4.6

Assume that d₁=r+1, namely there exists a polynomial g in F_{A}[x] of degree r+1, then dᵢ=i(r+1) for all i=0, . . . , m−1, and the polynomials 1, g, . . . , g^{m-1} defined in Proposition 4.5 part (3), form a basis for F_{A}[x].

Proof.

If there exists such a polynomial g, then clearly it takes distinct values on distinct sets of the partition A. Otherwise for some constant cεF, the polynomial g−c has at least 2(r+1) roots, and it is of degree r+1, which is a contradiction. Hence, by Proposition 4.5, part (3) the powers of g form a basis of the algebra, and the result follows.

Next let us use the properties of the algebra of polynomials defined by the partition A to construct (n,k,r) LRC codes.

Construction 2

Let A⊂F, |A|=n and let A a partition of the set A into

$$m = \frac{n}{r + 1}$$

sets of size r+1. Let Φ be an injective mapping from F^{k} to the space of polynomials

F_{A}^{r}=⊕ᵢ₌₀^{r-1}F_{A}[x]xⁱ.

Note that F_{A}^{r} is indeed a direct sum of the spaces, so dim(F_{A}^{r})=mr. Therefore such an injective mapping exists iff k≦mr=nr/(r+1).

The mapping Φ sends the set of messages F^{k} to a set of encoding polynomials. We construct a code by evaluating the polynomials fεΦ(F^{k}) at the points of A. If Φ is a linear mapping, then the resulting code is also linear.

This construction relies on an arbitrary mapping Φ:F^{k}→F_{A}^{r}. It forms a generalization of Construction 1 which used a particular linear mapping for the same purpose. Moreover the algebra F_{A}[x] in Construction 1 is generated by the powers of a polynomial of degree r+1, namely Corollary 4.6 is satisfied.

Below we write fₐ(x):=Φ(a).

Theorem 4.7

Construction 2 gives an (n,k,r) LRC code with minimum distance d satisfying

$$d \geq n - {max}_{a , b ∈ {F}^{k}} deg ( {f}_{a} - {f}_{b} ) \geq n - {max}_{a ∈ {F}^{k}} deg ( {f}_{a} ) . \qquad ( 18 )$$

Proof.

To prove local recoverability, we basically repeat the proof of Theorem 4.1. For a given message vector a let

$${f}_{a} ( x ) = {\sum }_{i = 0}^{r - 1} {f}_{i} ( x ) {x}^{i} , \qquad ( 19 )$$

Where the coefficient polynomials fᵢ(x) satisfy fᵢεF_{A}[x]. Choose jε{1 . . . , m} and suppose that the symbol to be recovered is fₐ(α), where αεAⱼ. Define the decoding polynomial

$$δ ( x ) = {\sum }_{i = 0}^{r - 1} {f}_{i} ( α ) {x}^{i} . \qquad ( 20 )$$

By (19), (20) δ(α)=fₐ(α). Since fᵢ belongs to F_{A}[x], for any β in Aⱼ we have fₐ(β)=δ(β). Moreover, since δ(x) is of degree at most r−1, it can be interpolated by accessing the r values of fₐ(β)=δ(β) for β in Aⱼ\α. We conclude that the value of the lost symbol fₐ(α) can be found by accessing the remaining r symbols in the block Aⱼ.

It remains to prove (18). Let (fₐ(α))_{αεA}, (f_{b}(α))_{αεA} be two codewords constructed from distinct message vectors a and b. Since Φ is injective and deg(fₐ−f_{b})<n, the code vectors that correspond to fₐ and f_{b} are distinct. Then (18) is immediate.

4.4 Systematic Form of Codes in Construction 1

In implementations it is preferable to have a systematic form of the LRC code in order to easily retrieve the stored information. Similarly to Reed-Solomon codes, it is possible to modify the encoding polynomial from the form (6), (19) to obtain systematic codes. Such a modification is briefly described in this section.

Let A={A₁, . . . , Aₘ}, m=n/(r+1) be a partition of the set A⊂F of size n into sets of size r+1. For i=1, . . . , k/r let Bᵢ={β_{i,1}, . . . , β_{i,r}} be some subset of Aᵢ of size r. In our systematic encoding the message symbols will be written in the coordinates with locations in the sets Bᵢ.

Recall that the algebra F_{A}[x] has a basis of polynomials fᵢ that satisfy fᵢ(Aⱼ)=δ_{i,j} i, j=1, . . . , m (16). For each set Bᵢ define r polynomials φ_{i,j}, j=1, . . . , r of degree less than r such that

φ_{i,j}(β_{i,l})=δ_{j,l}.

These polynomials can be easily found using Lagrange's interpolation. For k information symbols a=(a_{i,j}), i=1, . . . , k/r; j=1, . . . , r define the encoding polynomial

$${f}_{a} ( x ) = {\sum }_{i = 1}^{k / r} {f}_{i} ( x ) ( {\sum }_{j = 1}^{r} {a}_{i , j} {φ}_{i , j} ( x ) ) . \qquad ( 21 )$$

The encoding of the message a is defined by computing the vector (fₐ(α), αεA), see (8). It is easily verified that fₐεF_{A}^{r}, so each symbol has locality r. Furthermore, by definition we have

fₐ(β_{i,j})=a_{i,j},i=1, . . . ,k/r,j=1, . . . ,r,

so the code is indeed systematic.

Although (21) provides a systematic form of an (n,k,r) LRC code, optimality of the minimum distance is generally not guaranteed. This follows since the best bound on the degree of the encoding polynomial fₐ(x) is deg(fₐ)<n. If the algebra F_{A}[x] is generated by the powers of a good polynomial g (see Proposition 4.5, part (3)) then it is possible to construct a systematic optimal LRC code. Indeed, one has to replace each polynomial fᵢ in (21) with the polynomial fᵢ that is a linear combination of the polynomials 1, g, . . . , g^{(k/r)-1} and satisfies fᵢ(Aⱼ)=δ_{i,j} for all j=1, . . . , k/r. This is possible since the matrix V=(g^{j-1}(Aᵢ)) is a Vandermonde matrix and thus invertible. Clearly the degree of each fᵢ is at most ((k/r)−1)(r+1). Therefore the degree of fₐ (x) is at most k+(k/r)−2, and optimality of the distance follows.

LRC Codes with Multiple Recovering Sets

In this section we extend the original local recoverability problem in one more direction, requiring each symbol to have more than one recovering set of r symbols. Having in mind the applied nature of the problem, we will assume that the different recovering sets for the given symbol are disjoint. Indeed, in distributed storage applications there are subsets of the data that are accessed more often than the remaining contents (they are termed “hot data”). In the case that such segments are accessed simultaneously by many users of the system, the disjointness property ensures that multiple read requests can be satisfied concurrently and with no delays.

Let us give a formal definition. Let F be a finite field. A code C⊂Fⁿ is said to be locally recoverable with t recovering sets (an LRC(t) code) if for every iε{1, . . . , n} there exist disjoint subsets Aᵢⱼ⊂[n]\i, j=1, . . . , t of size r₁, . . . rₜ respectively, such that for any codeword xεC, the value of the symbol xᵢ is a function of each of the subsets of symbols {xₗ, lεA_{i,j}}, j=1, . . . , t. We write (n,k,{r₁, . . . , rₜ}) LRC code to refer to a LRC(t) code of dimension k, length n, and t disjoint recovering sets of size rᵢ=1, . . . , t.

We will present two methods to construct LRC codes with multiple recovering sets, both relying on the construction of the previous section. The first method relies on the combinatorial concept of orthogonal partitions, extending the basic construction to multiple recovering sets. The second method uses the construction of product codes and graph codes to combine several LRC codes into a longer multiple recovering code. For simplicity of presentation we will restrict ourselves to codes with two recovering sets, although both constructions clearly apply for any number of recovering sets.

5.1 Algebraic LRC Codes with Multiple Recovering Sets

In this section we present a construction of LRC codes with multiple disjoint recovering sets that develops the method of Sect. 4. As in the case for single recovering set, the construction will utilize the additive and multiplicative structure of the field.

Let A⊂F, |A|=n and let A (respectively, A′) be a partition of A into disjoint sets of size r+1 (resp., (s+1)). Define two subspaces of polynomials

F_{A}^{r}=⊕ᵢ₌₀^{r-1}F_{A}[x]xⁱ and F_{A′}^{s}=ᵢ₌₀^{s-1}F_{A′}[x]xⁱ, (22)

Where the notation F_{A}[x] is defined in (15). Clearly

$$dim ( {F}_{A}^{r} ) = r \frac{n}{r + 1} , \\ dim ( {F}_{{A}^{′}}^{s} ) = s \frac{n}{s + 1} .$$

For an integer m let Pₘ be the space of polynomials of degree less than m, and define

Vₘ=F_{A}^{r}∩F_{A′}^{s}∩Pₘ, (23)

to be the space of polynomials of degree less than m that also belong to F_{A}^{r} and F_{A′}^{s}.

Construction 3

Let A, A₁, A₂ be as above. Assume that dim(F_{A}^{r}∩F_{A′}^{s})≧k and let m be the smallest integer such that dim(Vₘ)=k. Let Φ:F^{k}→Vₙ, be an injective mapping. For simplicity we assume that this mapping is linear, i.e., there exits a polynomial basis g₀, . . . , gₖ₋₁ of Vₘ such that

$$Φ ( a ) = {\sum }_{i = 0}^{k - 1} {a}_{i} {g}_{i} ( x ) .$$

Denote by fₐ(x)=Φ(a) the encoding polynomial for the vector a. Construct the code as the image of F^{k} under the evaluation map similarly to (8).

Theorem 5.1

Construction 3 gives an (n, k, {r, s}) LRC code C with distance at least n−m+1.

Proof.

The claim about the distance is obvious from the construction (it applies even if the mapping Φ is nonlinear). The local recoverability claim is proved as follows. Since the encoding polynomial fₐ is in F_{A}^{r}, there exist r polynomials f₀, . . . , fᵣ₋₁ in F_{A}[x] such that

$${f}_{a} ( x ) = {\sum }_{i = 0}^{r - 1} {f}_{i} ( x ) {x}^{i} .$$

Now we can refer to Theorem 4.7. Using the arguments in its proof, every symbol of the codeword can be recovered by accessing the r symbols from the block of the partition A that contains it, as well as by accessing the s symbols from the corresponding block of the partition A′. The result follows.

Call partitions A and A′ orthogonal if

|X∩Y|≦1 for all XεA,YεA′.

If the partitions A and A′ are orthogonal, then every symbol of the code constructed above has two disjoint recovering sets of size r and s, respectively.

In the following example we will construct an LRC(2) using Construction 3 and two orthogonal partitions.

### Example 5

Let F=F₁₃, A=F\{0}, and let A and A′ be the orthogonal partitions defined by the cosets of the multiplicative cyclic groups generated by 5 and 3, respectively. We have

A={{1,5,12,8},{2,10,11,3},{4,7,9,6}}

A′={{1,3,9},{2,6,5},{4,12,10},{7,8,11}}. (24)

Since |A|=3, by Proposition 4.5, dim(F_{A}[x])=3, and similarly, dim(F_{A}[x])=4. It is easy to check that

F_{A}[x]= [symbol] 1,x⁴,x⁸ [symbol] ,F_{A′}[x]= [symbol] 1,x³,x⁶,x⁹ [symbol] .

Moreover by (22)

F_{A}^{r} ∩F_{A′}^{s}= [symbol] 1,x,x²,x⁴,x⁵,x⁶,x⁸,x⁹,x¹⁰ [symbol] ∩ [symbol] 1,x,x³,x⁴,x⁶,x⁷,x⁹,x¹⁰ [symbol] = [symbol] 1,x,x⁴,x⁶,x⁹,x¹⁰ [symbol] . (25)

Let m=7, then Vₘ= [symbol] 1,x,x⁴,x⁶ [symbol] . (26)

We will construct a (12,4,{2,3}) LRC code with distance d≧6. By Construction 3 and (26), for a vector a=(a₀,a₁a₂,a₃)εF⁴ the encoding polynomial is

fₐ(x)=a₀+a₁x+a₂x⁴+a₃x⁶.

This polynomial can be written as

$${f}_{a} ( x ) = {\sum }_{i = 0}^{2} {f}_{i} ( x ) {x}^{i} , \\ where$$

$${f}_{0} ( x ) = {a}_{0} + {a}_{2} {x}^{4} , \\ {f}_{1} ( x ) = {a}_{1} , \\ {f}_{2} ( x ) = {a}_{3} {x}^{4} ,$$

and each fᵢεF_{A}[x]. The same polynomial can also be written as

$${f}_{a} ( x ) = {\sum }_{i = 0}^{1} {g}_{i} ( x ) {x}^{i}$$

$$where$$

$${g}_{0} ( x ) = {a}_{0} + {a}_{3} {x}^{6} , \\ {g}_{1} ( x ) = {a}_{1} + {a}_{2} {x}^{3} ,$$

and g₀, g₁εF_{A′}[x].

Assume that one would like to recover the value of the codeword symbol fₐ(1). This can be done in two ways as follows:

(1) Use the set in the partition A that contains 1, i.e., {1,5,12,8}, find the polynomial δ(x) of degree at most 2 such that δ(5)=fₐ(5), δ(12)=fₐ(12) and δ(8)=fₐ(8). The symbol fₐ(1) is found as fₐ(1)=δ(1);

or

(2) Use the set {1,3,9}εA′, which also contains 1, find the polynomial δ₁(x) of degree at most 1 such that δ₁(3)=fₐ(3), δ₁(9)=fₐ(9). The symbol fₐ(1) is found as f(1)=δ₁(1).

Finally, since deg fₐ≦6 for all aεFₖ, we immediately observe that d(C)≧6.

As observed above, orthogonality of the partitions is a desirable property in the context of simultaneous data recovery by different users. In (24) we constructed orthogonal partitions using cosets of two distinct subgroups of the field F. Of course, not every pair of subgroups has this property. It is easy to identify a necessary and sufficient condition for the subgroups to generate orthogonal partitions.

Proposition 5.2

Let H and G be two subgroups of some group, then the coset partitions H and G defined by H and G respectively are orthogonal iff the subgroups intersect trivially, namely

H∩G=1.

If the group X is cyclic, then it is equivalent to requiring that gcd(|H|,|G|)=1.

Proof.

Two distinct elements x, y in the group are in the same cosets in the partitions H and G if Hx=Hy and Gx=Gy, which is equivalent to xy⁻¹εH∩G and xy⁻¹≠1, and the first part follows. Now assume that the group is cyclic (e.g. the multiplicative group of a finite field), and let h=|H| and g=|G|. Elements x, y belong to the same coset in the partitions H and G iff the element xy⁻¹ is both an h-th and g-th root of unity. This happens if and only if the order ord(xy⁻¹) divides both h and g, or equivalently that ord(xy⁻¹)|gcd(h,g). Since x≠y, the order ord(xy⁻¹)>1, hence, gcd(h,g)≠1, which proves the second part.

In the context of finite fields we can use both the multiplicative group (as in the above example) and the additive group of the field to construct LRC(t).

### Example 6

In applications it is often useful to have codes over a field of characteristic 2, e.g., over the field F₁₆. We have F₁₆⁺≈F₄⁺×F₄⁺, and the two copies of F₄⁺ in F₁₆ intersect only by the zero element, hence by Proposition 5.2 they generate two orthogonal partitions. Using Construction 3, one can construct an LRC code of length 16 with two disjoint recovering sets for each symbol, each of size 3. The dimension of the code can be any integer k≦8.

Since the additive group of the field is a direct product of smaller groups, it is easy to find subgroups that intersect trivially, giving rise to orthogonal partitions of F_{q}. These partitions can be used to construct LRC(2) codes with disjoint recovering sets, as in the previous example.

At the same time, constructing LRC(2) codes from a multiplicative subgroup of F_{q}, q=p^{l} requires one extra condition, namely, that q−1 is not a power of a prime. In this case, we can find two subgroups of F_{q}* of coprime orders, which give rise to orthogonal partitions of F_{q}*.

Proposition 5.3

Let F_{q} be a finite field such that the q−1 is not a power of a prime. Let r,s>1,gcd(r,s)=1 be two factors of q−1. Then there exists an LRC(2) code C of length q−1 over F_{q} such that every code symbol has two disjoint recovering sets of sizes r−1 and s−1. The code C can be constructed using Construction 3 based on the subgroups of F_{q}* of orders r and s.

One sufficient condition for the existence of subgroups of coprime orders in the multiplicative group of Fₚ_{^{l}} is that 1 itself is not a power of a prime. Indeed, let l=ab, where a≦b and a does not divide b. In this case both (p^{a}−1)|(p^{l}−1) and (p^{b}−1)|(p^{l}−1). Then p^{l}−1 is not a power of a prime, because otherwise (p^{a}−1)|(p^{b}−1), i.e., a|b.

### Example 7

Using Construction 3 and the previous observation, one can construct an LRC(2) code of length 2⁶−1=63, in which every symbol has two disjoint recovering sets of size 2 and 6, respectively. This is done using the orthogonal partitions derived from the subgroups of size 3 and 7.

LRC codes with multiple disjoint recovering sets are likely to have large minimal distance since each erased symbol can be recovered in several ways, so the code is resilient against many erasures. In the following statement we quantify this argument by establishing a lower bound on the distance in terms of the number of recovering sets for each symbol. The next theorem applies to any class of LRC(t) codes such that the recovering sets for the symbols form t mutually orthogonal partitions.

Theorem 5.4

Let C be an LRC(t) code of length n, and suppose that the recovering sets are given by mutually orthogonal partitions A₁, . . . , Aₜ of [n]. Let m be the smallest positive integer that satisfies

$$tf ( m ) \leq ( \begin{matrix}m \\ 2\end{matrix} ) , \\ Where \\ f ( m ) = \{ \begin{matrix}\frac{m}{2} , & m even \\ \frac{m + 3}{2} , & m odd\end{matrix} . \qquad ( 27 )$$

Then the distance of C is at least m.

The proof relies on the following lemma.

Lemma 5.5

Let A₁, . . . , Aₜ be t mutually orthogonal partitions of a finite set A, and let m be defined in (27). Then for any B⊂A,|B|<m there exists a subset C in some partition Aᵢ, i=1, . . . , t such that |B∩C|=1.

Proof.

By definition of m for any integer s<m

$$tf ( s ) > ( \begin{matrix}s \\ 2\end{matrix} ) . \qquad ( 28 )$$

Assume toward a contradiction that the statement is false, then for every i=1, . . . , t and any element xεB, there exists yεB such that x, y belong to the same set in the partition Aᵢ. For a partition Aᵢ define the graph Gᵢ with the elements of B as its vertices, and draw an edge between x and y iff they are in the same set in the partition Aᵢ. By the assumption, the degree of every of Gᵢ is at least one. If s=|B| is even then there are at least s/2 edges in Gᵢ. If s is odd, then Gᵢ contains at least one triangle, and so there are at least (s−3)/2+3=(s+3)/2 edges in it. Notice that since the partitions are mutually orthogonal, there are no edges that are contained in more than one graph Gᵢ. Therefore

$$tf ( s ) \leq {\sum }_{i = 1}^{t} \vert E ( {G}_{i} ) \vert = \vert {⋃}_{i = 1}^{t} E ( {G}_{i} ) \vert \leq ( \begin{matrix}s \\ 2\end{matrix} ) ,$$

which is a contradiction to (28).

Proof of Theorem 5.4:

In order to prove that d(C)≧m we will show that any m−1 erased symbols in the codeword can be recovered. Let B be the set of m−1 erased coordinates. By Lemma 5.5 there exists a set C in some partition Aᵢ such that B∩C={i₁}, where i₁ε[n] is some coordinate. Since no other coordinates in the set C are erased, this permits us to recover the value of the symbol in the coordinate iₜ by accessing the symbols in the set C\{i₁}. This reduces the count of erasures by 1, leaving us with the set of erasures of cardinality m−2. Lemma 5.5 applies to it, enabling us to correct one more erasure, and so on.

### Example 8

Consider an (n=12, k=6, {r₁=2, r₂=3}) LRC code C over F₁₃ obtained using Construction 3, the partitions in (24), and the corresponding algebras F_{A}[x], F_{A′}[x]. Using (27) in Theorem 5.4 we find that the distance of C is at least 4.

By (25) the set {1, x, x⁴ x⁶, x⁹, x¹⁰} forms a basis of the space of encoding polynomials. Given a message vector a=(a₀,a₁,a₄,a₆,a₉,a₁₀)εF⁶, write the encoding polynomial as

fₐ(x)=a₀+a₁x+a₄x⁴+a₆x⁶+a₉x⁹+a₁₀x¹⁰.

To find the codeword, evaluate the polynomial at all nonzero elements of the field F₁₃.

Assume that the value fₐ(2) is erased and needs to be recovered. This can be done in two ways:

(1) Write the encoding polynomial as follows

fₐ(x)=(a₀+a₄x⁴)+x(a₁+a₉x⁸)+x²(a₆x⁴+a₁₀x⁸)=g₀+g₁(x)x+g₂(x)x²,

Where g₀=a₀+a₄x⁴, g₁(x)=a₁+a₉x⁸, g₂(x)=a₆x⁴+a₁₀x⁸, and gᵢεF_{A}[x], i=1, 2, 3.

The symbol fₐ(2) can be found from the values of fₐ(10), fₐ(11), fₐ(3).

(2) Write the encoding polynomial as follows

fₐ(x)=(a₀+a₆x⁶+a₉x⁹)+x(a₁+a₄x³+a₁₀x⁹)=f₀(x)+xf₁(x),

Where f₀(x)=a₀+a₆x⁶+a₉x⁹ and f₁(x)=aₗ+a₄x³+a₁₀x⁹, and f₀, f₁εF_{A′}[x]. The symbol fₐ(2) can be found from the values of fₐ(5), fₐ(6).

Remarks:

1. Since the polynomial fₐ in the above example can be of degree 10, bounding the codeword weight by the degree would only give the estimate d(C)≧2. We conclude that Theorem 5.4 can sometimes provide a better bound on the minimum distance compared to the degree estimate.

As discussed above, an obvious solution to the multi-recovery problem is given by repeating each symbol of the data several time. An advantage of this is high availability of data: Namely, a read request of a data fragment located on an unavailable or overloaded (hot) node can be easily satisfied by accessing the other replicas of the data. The LRC(2) code C constructed in the above example can be a good candidate to replace the repetition code, with almost no extra cost. Indeed, both the (12,6) LRC(2) code C and the (18,6) three-fold repetition code encode 6 information symbols, however the encoding C entails a 100% overhead compared to a 200% overhead in the case of repetition. The code C is resilient to any 3 erasures while the repetition code can fail to recover the data if all the 3 copies of the same fragment are lost. At the same time, the code C uses subsets of sizes 2 and 3 to calculate the value of the symbol while the repetition code in the same situation uses two subsets of size 1. Thus, the reduction of the overhead is attained at the expense of data availability.

In the final part of this section we derive a bound on the distance of the constructed codes confining ourselves to the basic case of the (n, k, {r, r}) code. This is accomplished by estimating the dimension of the subspace Vₘ defined in (23) and then using Theorem 5.1.

Lemma 5.6

Let A be a set of size n, and assume that A and A′ are two orthogonal partitions of A into subsets of size r+1. Suppose that there exists polynomials g and g′ of degree r+1 that are constant on the blocks of A and A′, respectively. Then the dimension of the space Vₘ (23) is at least m(r−1)/(r+1).

Proof.

Recall the space of polynomials F_{A}^{r} defined in (22). Let t=n/(r+1) and note that the basis of this subspace is given by the polynomials gⁱx^{j}, i=0, . . . , t−1, j=0, . . . , r−1. Since deg(g)=r+1, it is clear that any polynomial of degree less than n that is not congruent to r modulo r+1, is in F_{A}^{r}. Therefore for any integer m

$$dim ( {F}_{A}^{r} ⋂ {P}_{m} ) \geq \frac{mr}{r + 1}$$

And the same bound holds if A on the above line is replaced with A′. Then we obtain

$$dim ( {P}_{m} ) = m \geq dim ( ( {F}_{A}^{r} ⋂ {P}_{m} ) + ( {F}_{{A}^{′}}^{r} ⋂ {P}_{m} ) ) \geq \frac{mr}{r + 1} + \frac{mr}{r + 1} - dim ( {F}_{A}^{r} ⋂ {F}_{{A}^{′}}^{r} ⋂ {P}_{m} ) \text{)} .$$

(cf. (23)).

Solving for the dimension of the subspace F_{A}^{r}∩F_{A′}^{r}∩Pₘ=Vₘ, we obtain the claimed estimate.

Now suppose we have an (n, k, {r, r}) LRC code designed using Construction 3. Choosing

$$m = ⌈ \frac{k ( r + 1 )}{r - 1} ⌉$$

we observe that the dimension of Vₘ is at least k. Therefore, from Theorem 5.1 the distance of the code satisfies the inequality (29)

LRC Product Codes

Given a set of t LRC codes, one can construct an LRC(t) code by taking a direct product of the corresponding linear subspaces. Again for simplicity we confine ourselves to the case of t=2.

Construction 4

We construct an (n, k, {r₁, r₂}) LRC code with n=n₁n₂, k=k₁k₂ by combining two LRC codes with the parameters (nᵢ, kᵢ, rᵢ), i=1, 2 obtained by Construction 2. Suppose that the codes C₁ and C₂ are linear, and were constructed using linear injective mappings Φᵢ and evaluating sets AᵢεF, i=1, 2. Define the linear mapping

Φ=Φ₁ [symbol] Φ₂:F^{k}^{ᵢ}^{k}^{₂}→⊕ᵢ₌₀^{r}^{₁}⁻¹F_{A}_{₁}[x]xⁱ [symbol] ⊕ⱼ₌₀^{r}^{₂}⁻¹F_{A}_{₂}[y]y^{j},

Which is the tensor product of the mappings Φᵢ. Define the encoding polynomial for aεF^{k}^{₁}^{k}^{₂} to be

fₐ(x,y)=Φ(a).

The code is the image of F^{k} under the evaluation map applied on the set of pairs A₁×A₂.

The following simple proposition summarizes the properties of this construction.

Proposition 5.7

Let Cᵢ⊂Fⁿ^{ᵢ} be an (nᵢ,kᵢ,rᵢ) LRC code with minimum distance dᵢ, i=1, 2. Construction 4 yields an LRC(2) code with the parameters (n=n₁n₂, k=k₁k₂, {r₁, r₂}) and distance d=d₁d₂.

Proof.

Denote by Aᵢ=Π_{j≧1}Aⱼ⁽ⁱ⁾ the partitions of the evaluation sets used in constructing the codes Cᵢ, i=1, 2 (refer to Construction 2). Let aεF^{k} and let the corresponding encoding polynomial be fₐ(x, y). Suppose that, for some point (x₀, y₀)εA₁×A₂ we would like to compute in two ways the value of fₐ(x₀, y₀), by accessing r₁ and r₂ symbols, respectively. Observe that the univariate polynomial fₐ(x, y₀) is contained in ⊕ᵢ₌₀^{r}^{₁}⁻¹F_{A}_{₁} [x]xᵢ, and therefore fₐ(x₀, y₀) can be found from the symbols in the set {fₐ(α, y₀), αεAₘ⁽¹⁾\x₀}, where Aₘ⁽¹⁾εA₁ is the set that contains x₀. Similarly fₐ(x₀, y₀) can be recovered using the polynomial fₐ(x₀, y) and the symbols in the set {fₐ(x₀, β), βεAₜ⁽²⁾\y₀}, where Aₜ⁽²⁾εA₂ is the set that contains y₀. Hence, the symbol fₐ(x₀,y₀) has two disjoint recovering sets of size r₁, r₂, and the result follows.

For instance, taking two optimal component LRC codes C₁ and C₂ with the parameters (nᵢ, kᵢ, rᵢ), i=1, 2 we find the distance of their product to satisfy

$$d = ( {n}_{1} - {k}_{1} - ⌈ \frac{{k}_{1}}{r} ⌉ + 2 ) ( {n}_{2} - {k}_{2} - ⌈ \frac{{k}_{2}}{r} ⌉ + 2 ) \qquad ( 30 )$$

### Example 9

Let us construct an (81,16,{2,2}) LRC code C [symbol] C, where C is the optimal (9,4,2) LRC code constructed in Example 1. The encoding polynomial of C for a vector aε(F₁₃)⁴ is

fₐ(x)=a₀+a₁x+a₂x³+a₃x⁴.

Define the vector (b₀,b₁,b₂,b₃)=(0,1,3,4) and note that fₐ can be written as fₐ(x)=Σᵢ₌₀³aᵢx^{b}^{ᵢ}. For a vector aε(F₁₃)¹⁶, a=(a_{i,j}), i, j=0, . . . , 3 the encoding polynomial of the product code C [symbol] C is

$${f}_{a} ( x , y ) = {\sum }_{i , j = 0}^{3} {a}_{i , j} {x}^{{b}_{i}} {y}^{{b}_{j}} .$$

The codeword that corresponds to the message a is obtained by evaluating fₐ at the points of A×A, where A={1,3,9,2,6,5,4,12,10}.

Assume that the symbol fₐ(1,2) is erased and needs to be recovered. We can do it in two ways:

(1) Find the polynomial δ(x), degδ(x)≦1 such that δ(3)=fₐ(3,2), δ(9)=fₐ(9,2), and compute fₐ(1,2)=δ(1), or
(2) Find the polynomial δ₁(y), deg δ₁(y)≦1 such that δ₁(6)=fₐ(1,6),δ₁(5)=fₐ(1,5), and compute f(1,2)=δ₁(2).

We remark that product codes can be also viewed as codes on complete bipartite graphs. Replacing the complete graph with a general bi-regular graph, we obtain general bipartite graph codes. A bipartite graph code is a linear code in which the coordinates of the codeword are labeled by the edges of the graph, and a vector is a codeword if and only if the edges incident to every vertex satisfy a given set of linear constraints. For instance, if this set is the same for every vertex (and the graph is regular), we obtain a graph code in which the local constraints are given by some fixed code C₀ of length equal to the degree Δ of the graph.

Having in mind our goal of constructing LRC codes, we should take C₀ to be an LRC code of length Δ. This will give us a code with two recovering sets for every symbol, given by the vertices at both ends of the corresponding edge. The advantage of this construction over product codes is that the length Δ of the component code can be small compared to the overall code length n. We will confine ourselves to these brief remarks, referring the reader to the literature (e.g., [2]) for more details on bipartite graph codes including estimates of their parameters.

Comparing the Two Methods:

The most fundamental parameter of an erasure-correcting code is the minimum distance. To compare the two constructions, suppose that the desired parameters of the LRC(2) code are (n,k,{r,r}) LRC codes and use the expressions (29) and (30). For simplicity, let us compare the constructions in terms of the rate R=k/n and the normalized distance θ=d/n. Then for Construction 3 we obtain

$$θ \geq 1 - R \frac{r + 1}{r - 1} + O ( 1 \text{/} n )$$

While for the product construction (Construction 4) we obtain (30)

$$θ = ( 1 - {R}_{1} \frac{r + 1}{r} + O ( 1 \text{/} n ) ) ( 1 - {R}_{2} \frac{r + 1}{r} + O ( 1 \text{/} n ) )$$

Putting R₁=R₂=\sqrt{R} gives the largest value on the right, and we obtain

$$θ = {( 1 - \sqrt{R} \frac{r + 1}{1} + O ( 1 / n ) )}^{2}$$

We observe that Construction 3 gives codes with higher minimum distance than the product of two optimal codes if the target code rate satisfies

$$\begin{matrix}R \leq {( \frac{2 r ( r - 1 )}{2 {r}^{2} - 1} )}^{2} = {( 1 - \frac{1}{r} )}^{2} {( 1 + \frac{1}{2 {r}^{2}} + O ( \frac{1}{{r}^{4}} ) )}^{2} \\ \approx {( 1 - \frac{1}{r} )}^{2}\end{matrix}$$

(e.g., for r=4 the condition becomes R≦0.599).

At the same time, the product construction provides more flexibility in constructing LRC codes with multiple recovering sets because it gives multiple disjoint recovering sets by design. On the other hand, Construction 3 requires constructing several mutually orthogonal partitions with their corresponding good polynomials, which in many cases can be difficult to accomplish. Moreover, the product construction requires the field of size about \sqrt{n}, outperforming Construction 3 which relies on the field of size about n, where n is the code length. Concluding, each of the two constructions proposed has its advantages and disadvantages, and therefore is likely to be more suitable than the other one in certain applications.

Generalizations of the Main Construction

In this section we return to the problem of LRC codes with a single recovering set for each symbol, generalizing the constructions of Section 4 in several different ways. We begin with constructing an LRC code for arbitrary code length, removing the assumption that n is a multiple of r+1. We continue with a general method of constructing LRC codes with recovering sets of arbitrary given size, further extending the results of Section 4. One more extension that we consider deals with constructing optimal LRC codes in which each symbol is contained in a local code with large minimum distance.

6.1 Arbitrary Code Length

The constructions of Section 4 require the assumption that n is a multiple of r+1. To make the construction more flexible, let us modify the definition of the codes so that this constraint is relaxed. While the minimum distance of the codes presented below does not always meet the Singleton-type bound (2), we will show that for the case of linear codes it is at most one less than the maximum possible value. The only assumption that will be needed is that n mod(r+1)≠1.

As before, for M⊂F denote by

$${h}_{M} ( x ) = {\prod }_{α ∈ M} ( x - a )$$

the annihilator polynomial of the set M. In the following construction we assume that n is not a multiple of r+1. For simplicity we also assume that r divides k, however this constraint can be removed.

Construction 5

Let F be a finite field, and let A⊂F be a subset such that |A|=n,n mod(r+1)=s≠1. Let

$$m = ⌈ \frac{n}{r + 1} ⌉$$

and let A={A₁, . . . , Aₘ} be a partition of A such that |Aᵢ|=r+1,1≦i≦m−1 and 1<|Aₘ|s<r+1. Let Φᵢ:F^{k/r}→F_{A}[x], i=0, . . . , r−1 be injective mappings. Moreover, assume that Φₛ₋₁ is a mapping to the subspace of polynomials of F_{A}[x] that vanishes on the set Aₘ, i.e., the range of Φₛ₋₁ is the space {fεF_{A}[x]:f(a)=0∀aεAₘ}.

Given the input information vector a=(a₀, . . . , aᵣ₋₁)εF^{k}, where each aᵢ is a vector of dimension k/r, define the encoding polynomial as follows:

$$\begin{matrix}{f}_{a} ( x ) = {\sum }_{i = 1}^{s - 1} {Φ}_{i} ( {a}_{i} ) {x}^{i} + {\sum }_{i = s}^{r - 1} {Φ}_{i} ( {a}_{i} ) {x}^{i - s} {h}_{{A}_{m}} ( x ) \\ = {\sum }_{i = 0}^{s - 1} {f}_{i} ( x ) {x}^{i} + {\sum }_{i = s}^{r - 1} {f}_{i} ( x ) {x}^{i - s} {h}_{{A}_{m}} ( x ) ,\end{matrix}$$

where Φᵢ(aᵢ)=fᵢ(x)εF_{A}[x]. Finally, define the code as the image of the evaluation mapping similarly to (8).

Theorem 6.1

Construction 5 defines an (n,k,r) LRC code.

Proof.

Any symbol fₐ(α) for α in one of the sets A₁, . . . , Aₘ₋₁ can be locally recovered using the same decoding procedure as in Construction 2. This follows since the encoding polynomial fₐ(x) belongs to the space ⊕ᵢ₌₀^{r-1}F_{A}[x]xⁱ, and therefore this symbol can be recovered by accessing r symbols. The only special case is recovering symbols in the set Aₘ. By definition of Φₛ₋₁ and (31), the restriction of the encoding polynomial fₐ(x) to the set Aₘ is a polynomial of degree at most s−2. Hence in order to recover the value of fₐ(α) for an element αεAₘ, we find the polynomial δ(x)=Σᵢ₌₀^{s-2}fᵢ(α)xⁱ from the set of s−1 values δ(β)=fₐ(β), βεAₘ\{α}. Clearly the lost symbol is fₐ(α)=δ(α), and the locality property follows.

To estimate the value of the code distance consider the following modification of Construction 5.

Construction 6

Let F be a finite field, and let A⊂F be a subset such that |A|=n, n mod(r+1)=s≠0, 1. Assume also that k+1 is divisible by r (this assumption is nonessential).

Let A be a partition of A into m subsets A₁, . . . , Aₘ of sizes as in Construction 5. Let g(x) be a polynomial of degree r+1, such that its powers 1, g, . . . , g^{m-1} span the algebra F_{A}[x]. W.l.o.g. we can assume that g vanishes on the set Aₘ, otherwise one can take the powers of the polynomial g(x)−g(Aₘ) as the basis for the algebra.

Let a=(a₀, . . . , aᵣ₋₁)εF^{k} be the input information vector, such that each aᵢ for i≠s−1 is a vector of length (k+1)/r and aₛ₋₁ is of length

$$\frac{k + 1}{r} - 1.$$

Define the encoding polynomial

$${f}_{a} ( x ) = {\sum }_{i = 0}^{s - 2} {\sum }_{j = 0}^{\frac{k + 1}{r} - 1} {a}_{i , j} {g ( x )}^{j} {x}^{i} + {\sum }_{j = 1}^{\frac{k + 1}{r} - 1} {a}_{s - 1 , j} {g ( x )}^{j} {x}^{s - 1} + {\sum }_{i = s}^{r - 1} {\sum }_{j = 0}^{\frac{k + 1}{r}} {a}_{i , j} {g}^{j} ( x ) {x}^{i - s} {h}_{{A}_{M}} ( x ) . \qquad ( 32 )$$

The code is defined as the set of evaluations of fₐ(x), aεF^{k}.

Theorem 6.2

The code given by Construction 6 is an (n,k,r) LRC code with minimum distance satisfying

$$d \geq n - k - ⌈ \frac{k}{r} ⌉ + 1. \qquad ( 33 )$$

Note that the designed minimum distance in (33) is at most one less than the maximum possible value.

Proof.

Since the encoding is linear and the encoding polynomial in (32) is of degree at most

$$( \frac{k + 1}{r} - 1 ) ( r + 1 ) + ( r - 1 ) = k + 1 - r + \frac{k + 1}{r} - 1 + r - 1 = k + ⌈ \frac{k}{r} ⌉ - 1.$$

The bound (33) follows. The locality property follows similarly to Construction 5. Indeed, if the symbol fₐ(α) for αεAₘ is to be recovered, we need to find a polynomial of degree at most s−2 from s−1 interpolation points, and the result follows.

6.2 LRC Codes as Redundant Residue Codes

So far in this disclosure we have discussed the problem of recovering the lost symbol of the codeword by accessing a specific subset of r other symbols. We presented a construction of optimal LRC codes with this functionality and several of its modifications. Of course, in order to locally recover a lost symbol, all the r other symbols must be accessible. Having in mind the distributed storage application, we argue that this may not always be the case, for instance, if the symbols of the codeword are distributed across a network, and some nodes of the network become temporarily inaccessible. For this reason, in this section we consider a general method of constructing (n,k,r) LRC codes such that every symbol is contained in an MDS local code with arbitrary parameters.

More formally, for an integer t let n₁, . . . , nₜ and k₁, . . . , kₜ be two sequences of integers that satisfy

$$k \leq {\sum }_{i} {k}_{i} , n = {\sum }_{i} {n}_{i} and {k}_{i} \leq {n}_{i} for any i .$$

We will construct a code such that its symbols can be partitioned into t codes Cᵢ, and each Cᵢ is an (nᵢ,kᵢ) MDS code. The idea of the construction in this section is similar to the description of Reed-Solomon codes as redundant residue codes [1]4, Sect. 10. which relies on the Chinese Remainder Theorem.

Chinese Remainder Theorem:

Let G₁(x), . . . , Gₜ(x)εF[x] be pairwise coprime polynomials, then for any t polynomials M₁(x), . . . , Mₜ(x)εF[x] there exists a unique polynomial f(x) of degree less than Σᵢdeg(Gᵢ), such that

f(x)≡Mᵢ(x)mod Gᵢ(x) for all i=1, . . . ,t.

Construction 7

Let A⊂F, |A|=n be a subset of points, and let A={A₁, . . . , Aₜ} be a partition of A such that |Aᵢ|=nᵢ, i=1, . . . , t. Let Ψ be an injective mapping

Ψ:F^{k}→Fₖ_{₁}[x]× . . . ,Fₖ_{ₜ}[x]

a|→(M₁(x), . . . ,Mt(x)),

Where Fₖ_{ᵢ}[x] is the space of polynomials of degree less than kᵢ, i=1, . . . , t. Let

$${G}_{i} ( x ) = {\prod }_{a ∈ {A}_{i}} ( x - a ) , i = 1 , … , t$$

be the annihilator polynomial of the subset Aᵢ. Clearly the polynomials Gᵢ(x) are pairwise coprime.

For a message vector aεF^{k} define the encoding polynomial fₐ(x) to be the unique polynomial of degree less than n that satisfies

fₐ(x)≡Mᵢ(x)mod Gᵢ(x).

Finally, the code is defined as the image of the evaluation map (8) for the set of message vectors F^{k}.

Theorem 6.3

Construction 7 constructs an (n,k) LRC code with t disjoint local codes Cᵢ, where each Cᵢ is an (nᵢ, kᵢ) MDS code.

Proof.

Since each codeword is an evaluation at n points of a polynomial of degree less than n, the weight of each nonzero codeword is at least one, and the code defined by the construction is indeed an injective mapping of F^{k} to Fⁿ.

Consider the set Aᵢ, i=1, . . . , t in the partition and note that by the construction, there exists a polynomial h such that

fₐ(x)=h(x)Gᵢ(x)+Mᵢ(x).

This implies that f(α)=Mᵢ(α) for any α in Aᵢ. In other words, the restriction of the codeword (fₐ(α), αεA) to the subset of locations corresponding to Aᵢ can be viewed as an evaluation of a polynomial of degree less than kᵢ at nᵢ points. In other words, the vectors (fₐ(α), αεAᵢ) form an (nᵢ, kᵢ) MDS code for all i=1, . . . , t.

The distance of the code constructed using the method discussed here is at least min_{1≦i≦t}(nᵢ−kᵢ+1). It is easy to see that Construction 2 and Construction 1 are a special case of Construction 7, where each local code is an (r+1,r) MDS code. Note also that Construction 7 provides significant flexibility, allowing one to combine arbitrary local MDS codes into an LRC code.

6.3 (r+ρ−1,r) Local MDS Codes

The construction considered in this section is a special case of the general construction of the previous section in which all the local codes have the same parameters. More specifically, we consider LRC codes in which the set of coordinates is partitioned into several subsets of cardinality r+ρ−1 in which every local code is an (r+ρ−1,r) MDS code, where ρ≧3. Under this definition, any symbol of the codeword is a function of any r out of the r+ρ−2 symbols, increasing the chances of successful recovery. Such codes will be called (n, k, r, ρ) LRC codes, where n is the block length and k is the code dimension (here we confine ourselves to the case of linear codes). Kamath et al. [1] generalized the upper bound (2) to (n, k, r, ρ) LRC codes, showing that the minimum distance d satisfies

$$d \leq n - k + 1 - ( ⌈ \frac{k}{r} ⌉ - 1 ) ( ρ - 1 ) . \qquad ( 34 )$$

As before, we will say that the LRC code is optimal if its minimum distance attains this bound with equality.

We assume that n|(r+ρ−1) and r|k, although the latter constraint is again unessential. The following construction is described for the case of linear codes, generalizing Construction 1. It is also possible to extend the more general Construction 2 to the case at hand, however we will not include the details.

Construction 8

Let A={A₁, . . . , Aₘ}, m=n/(r+ρ−1) be a partition of the set A⊂F, |A|=n, such that |Aᵢ=r+ρ−1, 1≦i≦m. Let gεF[x] be a polynomial of degree r+ρ−1 that is constant on each of the sets Aᵢ. The polynomials 1, g, . . . , g^{m-1} span the algebra F_{A}[x], see Proposition 4.5 part (3). For an information vector aεF^{k} define the encoding polynomial

$${f}_{a} ( x ) = {\sum }_{i mod ( r + ρ - 1 ) = 0 , 1 , … , r - 1}^{k - 1 + ( \frac{k}{r} - 1 ) ( ρ - 1 )} {a}_{i} {g ( x )}^{⌊ \frac{i}{r + ρ - 1} ⌋} {x}^{i mod ( r + ρ - 1 )} . \qquad ( 35 )$$

The code is the image of F^{k} under the evaluation map, see (8).

We note that the polynomial fₐ(x) can be also represented in the form analogous to (6). Indeed, let a=(a₀, . . . , aᵣ₋₁)εF^{k}, where each

$${a}_{i} = ( {a}_{i , 0} , … , {a}_{i , \frac{k}{r} - 1} )$$

is a vector of length k/r. For i=0, . . . , r−1 define

$${f}_{i} ( x ) = {\sum }_{j = 0}^{\frac{k}{r} - 1} {a}_{ij} {g ( x )}^{j} ,$$

Then (35) becomes

$${f}_{a} ( x ) = {\sum }_{i = 0}^{r - 1} {f}_{i} ( x ) {x}^{i} ,$$

Theorem 6.4

Construction 8 yields an optimal (n,k,r,ρ) LRC code.

Proof.

Since the degree of the encoding polynomial satisfies

$$deg ( {f}_{a} ) \leq k - 1 + ( ⌈ \frac{k}{r} ⌉ - 1 ) ( ρ - 1 )$$

and the code is linear, we conclude that the bound on the code distance in (34) is achieved with equality. The local recoverability property follows similarly to Theorem 4.1. Indeed, suppose that the erased symbol is fₐ(α) for some α in Aᵢ. The restriction of fₐ to the set Aᵢ is a polynomial of degree at most r−1. At the same time, |Aᵢ\{α}|=r+ρ−2, so fₐ can be reconstructed from any r of its values on the locations in Aᵢ. The theorem is proved.

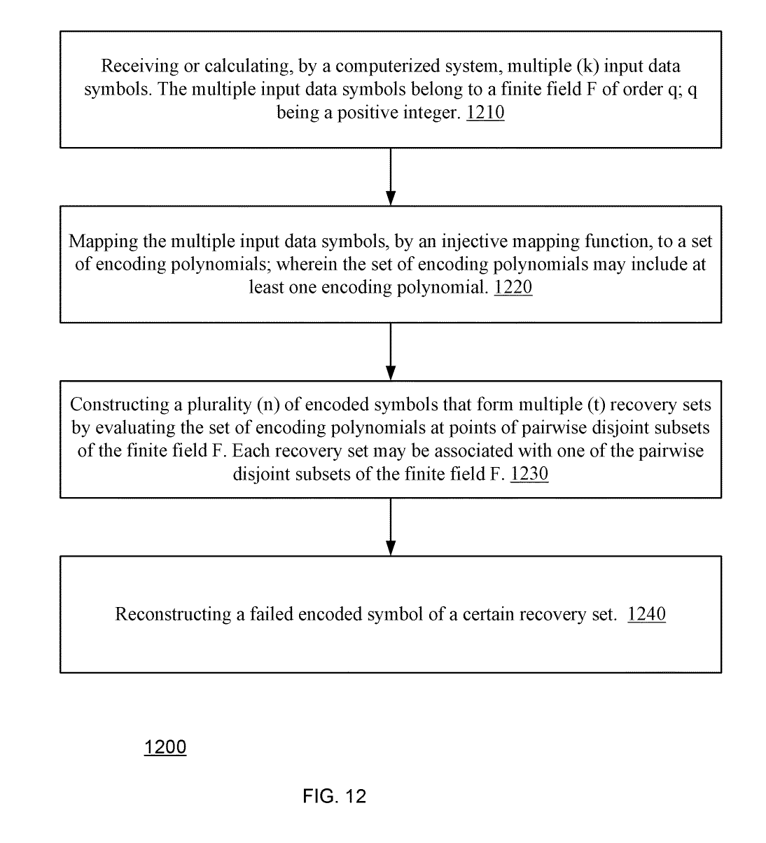

FIG. 12 illustrates method 1200 according to an embodiment of the invention. Various stages of method 1200 are illustrated in paragraphs 000153-000161, 000189-000195, 000247-000251, and 000368-000376.

Method 1200 may start by stage 1210 of receiving or calculating, by a computerized system, multiple (k) input data symbols. The multiple input data symbols belong to a finite field F of order q; q being a positive integer. The values of q may exceed n.

Stage 1210 may be followed by stage 1220 of mapping the multiple input data symbols, by an injective mapping function, to a set of encoding polynomials; wherein the set of encoding polynomials may include at least one encoding polynomial.

Stage 1220 may be followed by stage 1230 of constructing a plurality (n) of encoded symbols that form multiple (t) recovery sets by evaluating the set of encoding polynomials at points of pairwise disjoint subsets (A₁, . . . , Aₜ) of the finite field F. Each recovery set may be associated with one of the pairwise disjoint subsets of the finite field F.

The injective mapping may map multiple (k) elements of the finite field F to a product of multiple (t) spaces of polynomials, wherein a dimension of the i'th space of polynomials does not exceed the size of the i'th pairwise disjoint subset of the finite field F.

The injective mapping map may map elements of the finite field F to a direct sum of spaces.

According to an embodiment of the invention x is a variable, index i ranges between 1 and t, an i'th recovery set Aᵢ of multiple (t) recovery sets has a size nᵢ, index r does not exceed (nᵢ−1), a space (F [symbol] [x]) of polynomials that are constant on each of the pairwise disjoint subsets (A₁, . . . , Aₜ) of the finite field F, a direct sum of spaces of polynomials equals ⊕ᵢ₌₀^{r-1} F [symbol] _{[x]x}ⁱ.

Stage 1230 may include calculating, for each recovery set of the multiple recovery sets, (a) an annihilator polynomial of the recovery set, and (b) a mapped polynomial to which the recovery set is mapped to by an injective mapping function.

Stage 1230 may also include calculating an encoding polynomial in response to r coefficient polynomials.

Stage 1230 may include calculating an i'th coefficient polynomial fᵢ(x) by

$${f}_{i} ( x ) = {\sum }_{j = 0}^{\frac{k}{r} - 1} {a}_{ij} {g ( x )}^{j} ,$$

i=r−1, wherein g(x) is a polynomial that is constant on each of the recovery sets; and calculating the encoding polynomial fₐ(x) by

$${f}_{a} ( x ) = {\sum }_{i = 0}^{r - 1} {f}_{i} ( x ) {x}^{i} .$$

According to an embodiment of the invention for every value of i that ranges between 1 and t, stage 1230 may include calculating an i'th recovery set using the Chinese Remainder Theorem algorithm. This calculating may include calculating as follows

$${f}_{i} ( β ) = {\sum }_{i = 1}^{t} \{ {\sum }_{β ∈ {A}_{i}}^{ } \frac{{M}_{i} ( β )}{{\prod }_{m \neq i}^{ } {G}_{m} ( β )} {\prod }_{γ \neq {β}_{i}}^{ } \frac{x - γ}{β - γ} {\prod }_{m \neq i}^{ } {G}_{m} ( β ) \} ;$$

wherein index i ranges between 1 and t, for all element β belonging to an i'th pairwise disjoint subset of the finite field F, the injective mapping function maps the multiple input data symbols to a t-tuple of polynomials

M₁(x), . . . ,Mₜ(x)

, and Gᵢ(x) is the annihilator polynomial of the i'th recovery set, i=1, . . . , t.

At least two recovery sets of the multiple recovery sets differ from each other by size. Alternatively, all recovery sets of the multiple recovery sets have a same size.

There may be various relationships between the various variables and/or sizes mentioned in the application. For example, all recovery sets of the multiple recovery sets may have the same size, may differ from each other by size, or may have some recovery sets of the same size while others may differ from each other by size. For example, all the recovery sets may have a size that equals r+1, wherein t equals n/(r+1), wherein r exceeds one and is smaller than k. Yet for another example, r+1 divides n and r divides k. Yet for another example (r+1) may divide n and/or r may divide k.

Stage 1230 may be followed by stage 1240 of reconstructing a failed encoded symbol of a certain recovery set. Stage 1240 may include reconstructing the failed encoded symbol of a certain recovery set by processing non-failed encoded symbols of the certain recovery set.

Stage 1240 may include reconstructing at least two failed encoded symbols of a certain recovery set by processing non-failed encoded symbols of the certain recovery set.

It is noted that method 1200 may involve matrix multiplication. For example, stage 1220 and 1230 may be include multiplying a k-dimensional vector that may include the multiple input symbols by an encoding matrix G that has k rows and n columns and is formed of elements of the finite field F.

According to an embodiment of the invention stages 1220 and 1230 may include multiplying a k-dimensional vector that may include the multiple input symbols by an encoding matrix G′ that has k rows and n columns, wherein encoding matrix G′ equals a product of a multiplication of matrices A, G and D, wherein matrix G has k rows and n columns and is formed of elements of the finite field, matrix A has k rows and k columns and is an invertible matrix formed of elements of the finite field, and matrix D is a diagonal matrix.

According to an embodiment of the invention each pairwise disjoint subset may include (r+ρ−1) elements, wherein there are

$$\frac{n}{r + ρ - 1}$$

pairwise disjoint subsets, wherein ρ≧2 is a natural number, wherein a locality of each recovery set is r, wherein each recovery set includes (r+ρ−1) encoded symbols, wherein x is a variable, wherein t=n/(r+ρ−1), wherein for polynomials g(x) of a degree (r+ρ+1) that is constant on m pairwise disjoint subsets, the injective mapping maps elements from the finite field F to a linear space of polynomials over the finite field F spanned by the polynomials g(x)^{j}xⁱ for all

$$j = 0 , … , \frac{k}{r} - 1 , \\ i = 0 , … , r - 1.$$

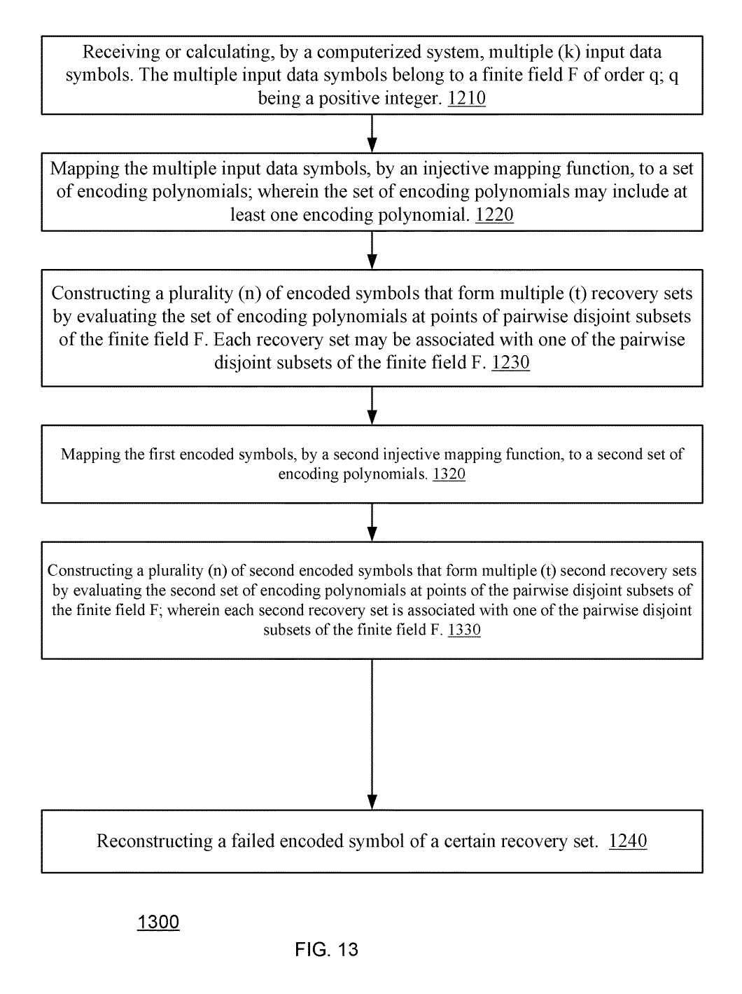

Although FIG. 12 illustrates a single iteration of stages 1220 and 1230 it is noted that multiple iterations of stages 1220 and 1230 may be executed. For example between 1 and (t−1) additional iterations may be executed. This is illustrated in FIG. 13. Alternatively, there may be a mapping that emulates an application of multiple mappings.

FIG. 13 illustrates method 1300 according to an embodiment of the invention. Various stages of method 1300 are illustrated in paragraphs 000321-000333 and 000268-000274.

Method 1300 starts by a sequence of stages 1210, 1220 and 1230.

During these stages the injective mapping function (that is applied) is a first mapping function, the recovery sets (generated during stage 1230) are first recovery sets; wherein the set of encoding polynomials (used in stage 1220) is a first set of encoding polynomials, the encoded symbols (calculated by stage 1230) are first encoded symbols.

Stage 1230 is followed by stage 1320 of mapping the first encoded symbols, by a second injective mapping function, to a second set of encoding polynomials.

Stage 1320 may be followed by stage 1330 of constructing a plurality (n) of second encoded symbols that form multiple (t) second recovery sets by evaluating the second set of encoding polynomials at points of the pairwise disjoint subsets of the finite field F; wherein each second recovery set is associated with one of the pairwise disjoint subsets of the finite field F.

Stage 1330 may be followed by stage 1240.

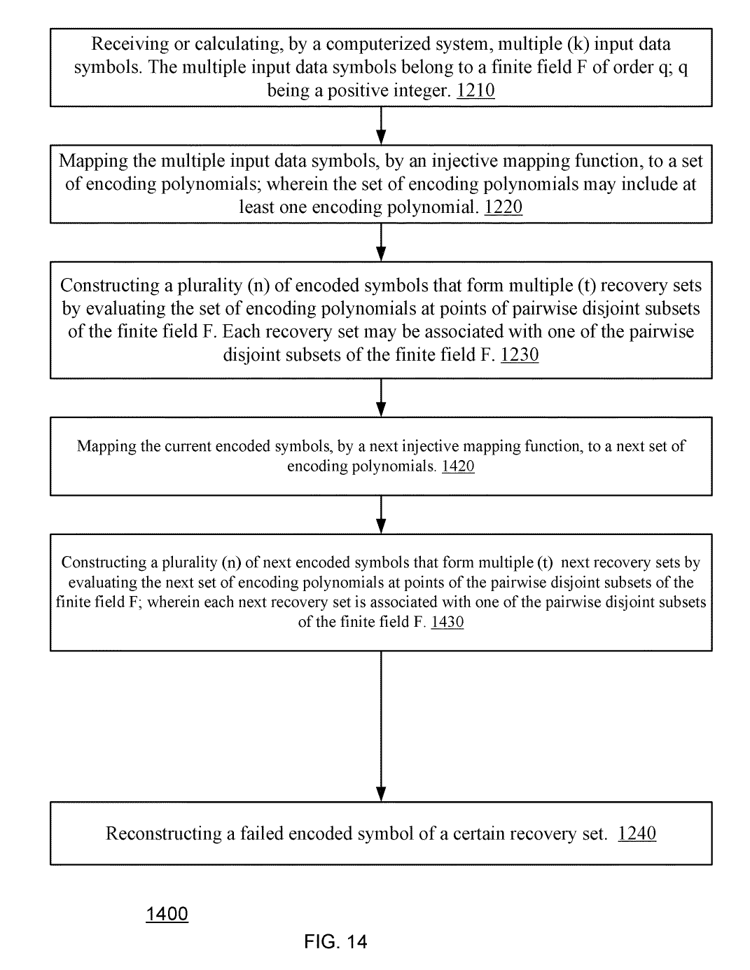

In general, there may be provided multiple iterations of the mapping and constructing stages. This is illustrated by FIG. 14.

FIG. 14 illustrates method 1400 according to an embodiment of the invention.

Method 1400 starts by a sequence of stages 1210, 1220 and 1230.

During these stages the injective mapping function is a current mapping function, the recovery sets are current recovery sets; the set of encoding polynomials is a current set of encoding polynomials, and the encoded symbols are current encoded symbols.

For t that exceeds one, for x that is a positive integer that ranges between 1 and (t−1); the method may include repeating, for x times the stages of: mapping (1420) the current encoded symbols, by a next injective mapping function, to a next set of encoding polynomials; and constructing (1430) a plurality (n) of next encoded symbols that form multiple (t) next recovery sets by evaluating the next set of encoding polynomials at points of the pairwise disjoint subsets of the finite field F; wherein each next recovery set is associated with one of the pairwise disjoint subsets of the finite field F.

Stage 1430 (after (t−1) iterations may be followed by stage 1240.

According to an embodiment of the invention at least two recovery sets may include content for reconstruction of a same encoded data symbol.

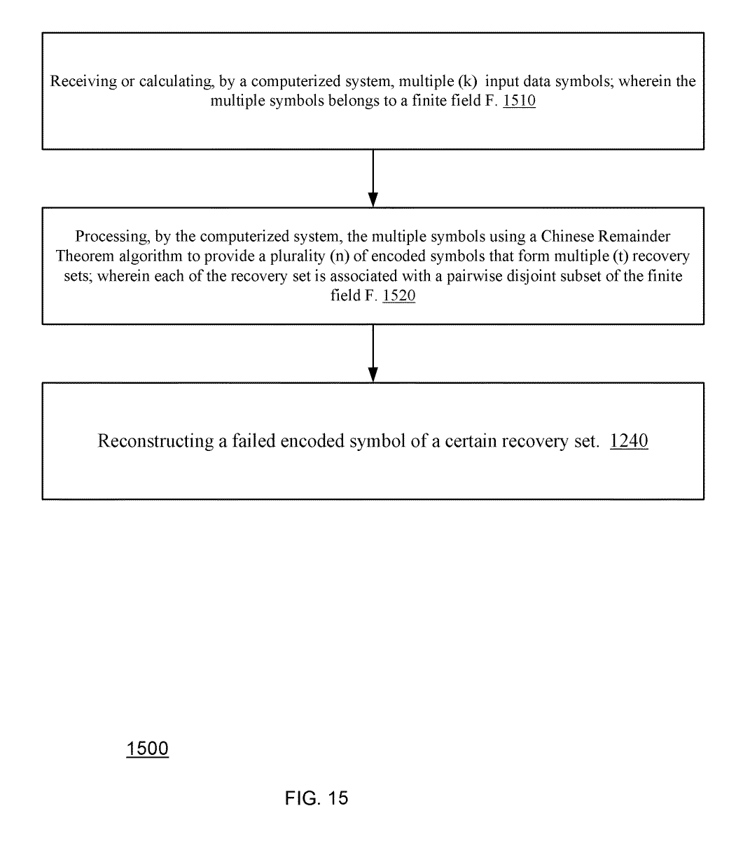

FIG. 15 illustrates method 1500 according to an embodiment of the invention.

Method 1500 may start by stage 1510 of receiving or calculating, by a computerized system, multiple (k) input data symbols; wherein the multiple symbols belongs to a finite field F. Various stages of method 1500 are illustrated in paragraphs 000368-000376.

Stage 1510 may be followed by stage 1520 of processing, by the computerized system, the multiple symbols using a Chinese Remainder Theorem algorithm to provide a plurality (n) of encoded symbols that form multiple (t) recovery sets; wherein each of the recovery set is associated with a pairwise disjoint subset of the finite field F.

Stage 1520 may be followed by stage 1240 of reconstructing a failed encoded symbol of a certain recovery set by processing non-failed encoded symbols of the certain recovery set.

According to an embodiment of the invention n does not exceed the number of elements of the finite field F.

Stage 1520 may include calculating, for each recovery set of the multiple recovery sets, (a) an annihilator polynomial of the recovery set, and (b) a mapped polynomial to which the recovery set is mapped to by an injective mapping function.

According to an embodiment of the invention for every value of i that ranges between 1 and t, an i'th recovery set is calculated by:

$${f}_{i} ( β ) = {\sum }_{i = 1}^{t} \{ {\sum }_{β ∈ {A}_{i}}^{ } \frac{{M}_{i} ( β )}{{\prod }_{m \neq i}^{ } {G}_{m} ( β )} {\prod }_{γ \neq {β}_{i}}^{ } \frac{x - γ}{β - γ} {\prod }_{m \neq i}^{ } {G}_{m} ( β ) \}$$

wherein index i ranges between 1 and t, wherein β belongs to the i'th recovery set, the injective mapping function maps the multiple input data symbols to t-tuple of polynomials

M₁(x), . . . ,Mₜ(x),

and Gᵢ(x) is the annihilator polynomial of the i'th recovery set.

According to an embodiment of the invention at least two recovery sets of the multiple recovery sets differ from each other by size.

According to an embodiment of the invention all recovery sets of the multiple recovery sets have a same size.

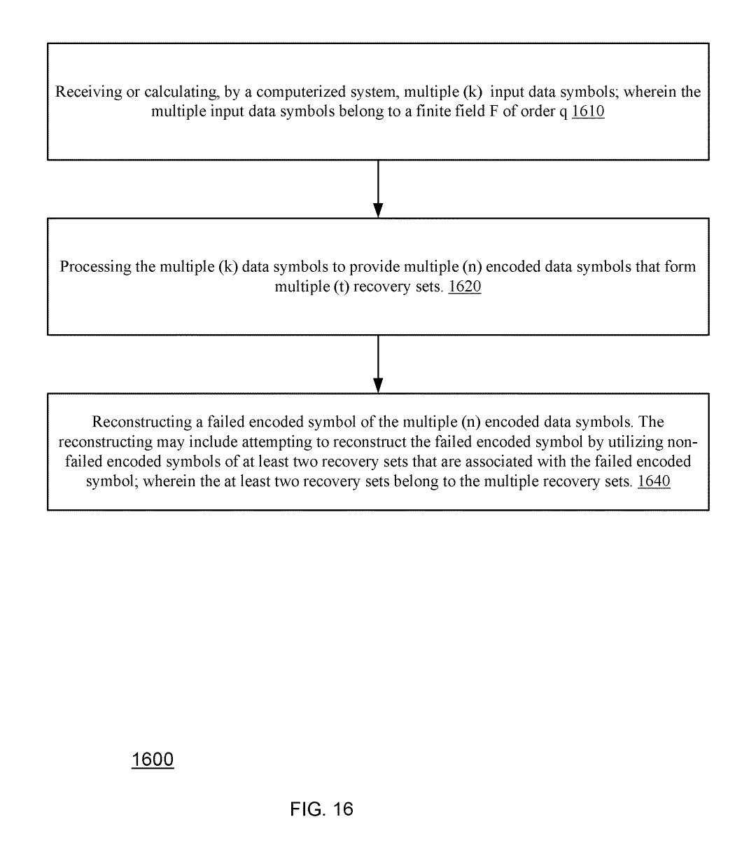

FIG. 16 illustrates method 1600 according to an embodiment of the invention. Various stages of method 1600 are illustrated in paragraphs 000329-000333 and 000268-000274.

Method 1600 may start by may start by stage 1610 of receiving or calculating, by a computerized system, multiple (k) input data symbols; wherein the multiple input data symbols belong to a finite field F of order q.

Stage 1610 may be followed by stage 1620 of processing the multiple (k) data symbols to provide multiple (n) encoded data symbols that form multiple (t) recovery sets.

Stage 1620 may be followed by stage 1630 of reconstructing a failed encoded symbol of the multiple (n) encoded data symbols. The reconstructing may include attempting to reconstruct the failed encoded symbol by utilizing non-failed encoded symbols of at least two recovery sets that are associated with the failed encoded symbol; wherein the at least two recovery sets belong to the multiple recovery sets.

According to an embodiment of the invention stage 1630 may include: performing a first attempt to reconstruct the failed encoded symbol by utilizing non-failed encoded symbols of a first recovery set of the at least two recovery sets; determining whether the first attempt failed; and performing a second attempt to reconstruct the failed encoded symbol by utilizing non-failed encoded symbols of a second recovery set of the at least two recovery sets if it is determined that the first attempt failed.

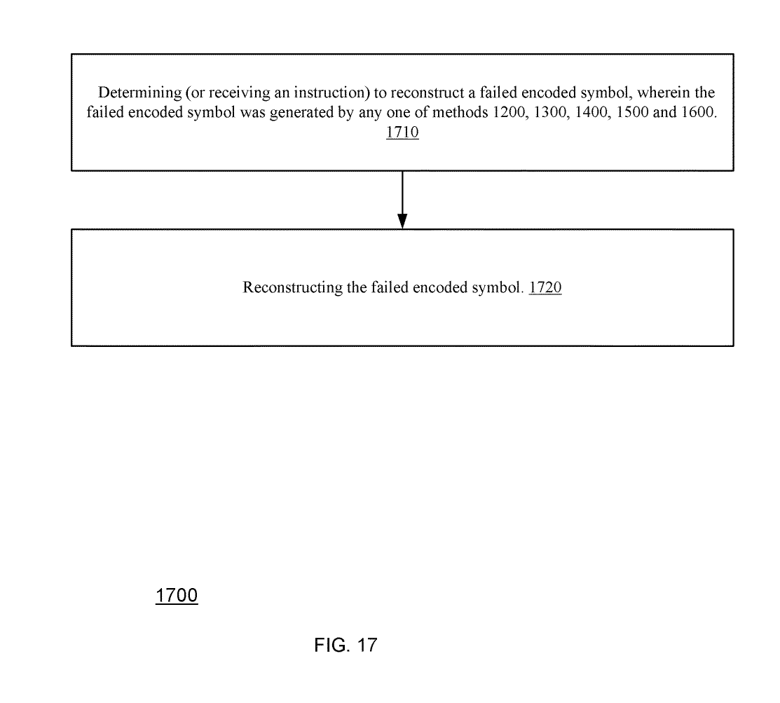

FIG. 17 illustrates method 1700 according to an embodiment of the invention. Various stages of method 1700 are illustrated in paragraphs 000159-000161.

Method 1700 may start by stage 1710 of determining (or receiving an instruction) to reconstruct a failed encoded symbol, wherein the failed encoded symbol was generated by any one of methods 1200, 1300, 1400, 1500 and 1600. Stage 1710 may be triggered by a failure of a storage device.

Stage 1710 may be followed by reconstructing the failed encoded symbol.

While the present disclosure has been described with reference to various embodiments, it will be understood that these embodiments are illustrative and that the scope of the disclosure is not limited to them. Various modifications and additions can be made to the exemplary embodiments discussed without departing from the scope of the present disclosure. For example, while the embodiments described above refer to particular features, the scope of this disclosure also includes embodiments having different combinations of features and embodiments that do not include all of the described features. Accordingly, the scope of the present disclosure is intended to embrace all such alternative, modifications, and variations together with all equivalents thereof.

The invention may also be implemented in a computer program for running on a computer system, at least including code portions for performing steps of a method according to the invention when run on a programmable apparatus, such as a computer system or enabling a programmable apparatus to perform functions of a device or system according to the invention. The computer program may cause the storage system to allocate disk drives to disk drive groups.

A computer program is a list of instructions such as a particular application program and/or an operating system. The computer program may for instance include one or more of: a subroutine, a function, a procedure, an object method, an object implementation, an executable application, an applet, a servlet, a source code, an object code, a shared library/dynamic load library and/or other sequence of instructions designed for execution on a computer system.

The computer program may be stored internally on a non-transitory computer readable medium. All or some of the computer program may be provided on computer readable media permanently, removably or remotely coupled to an information processing system. The computer readable media may include, for example and without limitation, any number of the following: magnetic storage media including disk and tape storage media; optical storage media such as compact disk media (e.g., CD-ROM, CD-R, etc.) and digital video disk storage media; nonvolatile memory storage media including semiconductor-based memory units such as FLASH memory, EEPROM, EPROM, ROM; ferromagnetic digital memories; MRAM; volatile storage media including registers, buffers or caches, main memory, RAM, etc.

A computer process typically includes an executing (running) program or portion of a program, current program values and state information, and the resources used by the operating system to manage the execution of the process. An operating system (OS) is the software that manages the sharing of the resources of a computer and provides programmers with an interface used to access those resources. An operating system processes system data and user input, and responds by allocating and managing tasks and internal system resources as a service to users and programs of the system.

The computer system may for instance include at least one processing unit, associated memory and a number of input/output (I/O) devices. When executing the computer program, the computer system processes information according to the computer program and produces resultant output information via I/O devices.

In the foregoing specification, the invention has been described with reference to specific examples of embodiments of the invention. It will, however, be evident that various modifications and changes may be made therein without departing from the broader spirit and scope of the invention as set forth in the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

The connections as discussed herein may be any type of connection suitable to transfer signals from or to the respective nodes, units or devices, for example via intermediate devices. Accordingly, unless implied or stated otherwise, the connections may for example be direct connections or indirect connections. The connections may be illustrated or described in reference to being a single connection, a plurality of connections, unidirectional connections, or bidirectional connections. However, different embodiments may vary the implementation of the connections. For example, separate unidirectional connections may be used rather than bidirectional connections and vice versa. Also, plurality of connections may be replaced with a single connection that transfers multiple signals serially or in a time multiplexed manner. Likewise, single connections carrying multiple signals may be separated out into various different connections carrying subsets of these signals. Therefore, many options exist for transferring signals.

Although specific conductivity types or polarity of potentials have been described in the examples, it will be appreciated that conductivity types and polarities of potentials may be reversed.

Each signal described herein may be designed as positive or negative logic. In the case of a negative logic signal, the signal is active low where the logically true state corresponds to a logic level zero. In the case of a positive logic signal, the signal is active high where the logically true state corresponds to a logic level one. Note that any of the signals described herein may be designed as either negative or positive logic signals. Therefore, in alternate embodiments, those signals described as positive logic signals may be implemented as negative logic signals, and those signals described as negative logic signals may be implemented as positive logic signals.

Furthermore, the terms “assert” or “set” and “negate” (or “deassert” or “clear”) are used herein when referring to the rendering of a signal, status bit, or similar apparatus into its logically true or logically false state, respectively. If the logically true state is a logic level one, the logically false state is a logic level zero. And if the logically true state is a logic level zero, the logically false state is a logic level one.

Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures may be implemented which achieve the same functionality.

Any arrangement of components to achieve the same functionality is effectively “associated” such that the desired functionality is achieved. Hence, any two components herein combined to achieve a particular functionality may be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

Also for example, in one embodiment, the illustrated examples may be implemented as circuitry located on a single integrated circuit or within a same device. Alternatively, the examples may be implemented as any number of separate integrated circuits or separate devices interconnected with each other in a suitable manner.

Also for example, the examples, or portions thereof, may implemented as soft or code representations of physical circuitry or of logical representations convertible into physical circuitry, such as in a hardware description language of any appropriate type.

Also, the invention is not limited to physical devices or units implemented in non-programmable hardware but can also be applied in programmable devices or units able to perform the desired device functions by operating in accordance with suitable program code, such as mainframes, minicomputers, servers, workstations, personal computers, notepads, personal digital assistants, electronic games, automotive and other embedded systems, cell phones and various other wireless devices, commonly denoted in this application as ‘computer systems’.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

We claim:

1. A method for encoding multiple data symbols, the method comprising:
receiving or calculating, by a computerized system, multiple (k) input data symbols; wherein the multiple input data symbols belong to a finite field F of order q; q being a positive integer;
mapping the multiple input data symbols, by an injective mapping function, to a set of encoding polynomials; wherein the set of encoding polynomials comprises at least one encoding polynomial; and
constructing a plurality (n) of encoded symbols that form multiple (t) recovery sets by evaluating the set of encoding polynomials at points of pairwise disjoint subsets (A₁, . . . , Aₜ) of the finite field F; wherein each recovery set is associated with one of the pairwise disjoint subsets of the finite field F.

2. The method according to claim 1 wherein the injective mapping maps multiple (k) elements of the finite field F to a product of multiple (t) spaces of polynomials, wherein a dimension of the i'th space of polynomials does not exceed the size of the i'th pairwise disjoint subset of the finite field F.

3. The method according to claim 1 wherein the injective mapping maps elements of the finite field F to a direct sum of spaces.

4. The method according to claim 3 wherein x is a variable, wherein index i ranges between 1 and t, wherein an i'th recovery set of multiple (t) recovery sets has a size nᵢ, wherein index r does not exceed (nᵢ−1), and a space (F [symbol] [x]) of polynomials that are constant on each of the pairwise disjoint subsets (A₁, . . . , Aₜ) of the finite field F, wherein a direct sum of spaces of polynomials equals ⊕ᵢ₌₀^{r-1}F [symbol] [x]xⁱ.

5. The method according to claim 1 further comprising reconstructing a failed encoded symbol of a certain recovery set by processing non-failed encoded symbols of the certain recovery set.

6. The method according to claim 1 wherein the processing comprises calculating, for each recovery set of the multiple recovery sets, a recovery set that is responsive to (a) elements that belong to the recovery set, (b) an annihilator polynomial of the recovery set, and (c) a mapped polynomial to which the recovery set is mapped to by an injective mapping function.

7. The method according to claim 6 wherein for every value of i that ranges between 1 and t, the symbols comprising the i'th recovery set are calculated using the Chinese Remainder Theorem algorithm as follows:
$${f}_{i} ( β ) = {\sum }_{i = 1}^{t} \{ {\sum }_{β ∈ {A}_{i}}^{ } \frac{{M}_{i} ( β )}{{\prod }_{m \neq i}^{ } {G}_{m} ( β )} {\prod }_{γ \neq {β}_{i}}^{ } \frac{x - γ}{β - γ} {\prod }_{m \neq i}^{ } {G}_{m} ( β ) \} ;$$
wherein index i ranges between 1 and t, for all element β belonging to an i'th pairwise disjoint subset of the finite field F, the injective mapping function maps the multiple input data symbols to a t-tuple of polynomials M₁(x), . . . , Mₜ(x), and Gᵢ(x) is the annihilator polynomial of the i'th recovery set, i=1, . . . , t.

8. The method according to claim 1 wherein at least two recovery sets of the multiple recovery sets differ from each other by size.

9. The method according to claim 1 wherein all recovery sets of the multiple recovery sets have a same size.

10. The method according to claim 1 wherein all recovery sets of the multiple recovery sets have a size that equals r+1, wherein t equals n/(r+1), wherein r exceeds one and is smaller than k.

11. The method according to claim 10 wherein r+1 divides n and r divides k.

12. The method according to claim 10 comprising reconstructing at least two failed encoded symbols by processing non-failed encoded symbols.

13. The method according to claim 10 comprising calculating an encoding polynomial in response to r coefficient polynomials.

14. The method according to claim 13 comprising calculating an i'th coefficient polynomial
$${f}_{i} ( x ) by {f}_{i} ( x ) = {\sum }_{j = 0}^{\frac{k}{r} - 1} {a}_{ij} {g ( x )}^{j} ,$$
i=0, . . . , r−1, wherein g(x) is a polynomial that is constant on each of the recovery sets; and calculating the encoding polynomial fₐ(x) by
$${f}_{a} ( x ) = {\sum }_{i = 0}^{r - 1} {f}_{i} ( x ) {x}^{i} .$$

15. The method according to claim 1 wherein the mapping and the constructing comprises multiplying a k-dimensional vector that comprises the multiple input symbols by an encoding matrix G that has k rows and n columns and is formed of elements of the finite field F.

16. The method according to claim 1 wherein the mapping and the constructing comprises multiplying a k-dimensional vector that comprises the multiple input symbols by an encoding matrix G′ that has k rows and n columns, wherein encoding matrix G′ equals a product of a multiplication of matrices A, G and D, wherein matrix G has k rows and n columns and is formed of elements of the finite field, matrix A has k rows and k columns and is an invertible matrix formed of elements of the finite field, and matrix D is a diagonal matrix.

17. The method according to claim 1 wherein each pairwise disjoint subset includes (r+ρ−1) elements, wherein there are
$$\frac{n}{r + ρ - 1}$$
pairwise disjoint sunsets, wherein ρ≧2 is a natural number, wherein a locality of each recovery set is r, wherein each recovery set includes (r+ρ−1) encoded symbols, wherein x is a variable, wherein t=n/(r+ρ−1), wherein for a polynomial g(x) of a degree (r+ρ+1) that is constant on t pairwise disjoint subsets, the injective mapping maps elements from the finite field F to a linear space of polynomials over the finite field F spanned by the polynomials g(x)^{j}xⁱ for all j=0, . . . ,
$$\frac{k}{r} - 1 ,$$
i=0, . . . , r−1.

18. The method according to claim 1 wherein the injective mapping function is a first mapping function, wherein the recovery sets are first recovery sets; wherein the set of encoding polynomials is a first set of encoding polynomials, wherein the encoded symbols are first encoded symbols; wherein the method comprises:
mapping the first encoded symbols, by a second injective mapping function, to a second set of encoding polynomials; and
constructing a plurality (n) of second encoded symbols that form multiple (t) second recovery sets by evaluating the second set of encoding polynomials at points of the pairwise disjoint subsets of the finite field F; wherein each second recovery set is associated with one of the pairwise disjoint subsets of the finite field F.

19. The method according to claim 1 wherein the injective mapping function is a current mapping function, wherein the recovery sets are current recovery sets; wherein the set of encoding polynomials is a current set of encoding polynomials, wherein the encoded symbols are current encoded symbols; wherein t exceeds one; wherein x is a positive integer that ranges between 1 and (t−1); wherein the method comprises repeating for x times the stages of: mapping the current encoded symbols, by a next injective mapping function, to a next set of encoding polynomials; and constructing a plurality (n) of next encoded symbols that form multiple (t) next recovery sets by evaluating the next set of encoding polynomials at points of the pairwise disjoint subsets of the finite field F; wherein each next recovery set is associated with one of the pairwise disjoint subsets of the finite field F.

20. The method according to claim 1, wherein at least two recovery sets comprise content for reconstruction of a same encoded data symbol.

21. A method for encoding multiple data symbols, the method comprising: receiving or calculating, by a computerized system, multiple (k) input data symbols; wherein the multiple symbols belongs to a finite field F; and processing, by the computerized system, the multiple symbols using a Chinese Remainder Theorem algorithm to provide a plurality (n) of encoded symbols that form multiple (t) recovery sets; wherein each of the recovery set is associated with a pairwise disjoint subset of the finite field F.

22. The method according to claim 21 further comprising reconstructing a failed encoded symbol of a certain recovery set by processing non-failed encoded symbols of the certain recovery set.

23. The method according to claim 21, wherein n does not exceed the number of elements of the finite field F.

24. The method according to claim 21 wherein the processing comprises calculating, for each recovery set of the multiple recovery sets, a recovery set that is responsive to (a) elements that belong to the recovery set, (b) an annihilator polynomial of the recovery set, and (c) a mapped polynomial to which the recovery set is mapped to by an injective mapping function.

25. The method according to claim 24 wherein for every value of i that ranges between 1 and t, an i'th recovery set is calculated by:
$${f}_{i} ( β ) = {\sum }_{i = 1}^{t} \{ {\sum }_{β ∈ {A}_{i}}^{ } \frac{{M}_{i} ( β )}{{\prod }_{m \neq i}^{ } {G}_{m} ( β )} {\prod }_{γ \neq {β}_{i}}^{ } \frac{x - γ}{β - γ} {\prod }_{m \neq i}^{ } {G}_{m} ( β ) \}$$
wherein index i ranges between 1 and t, wherein β belongs to the i'th recovery set, the injective mapping function maps the multiple input data symbols to t-tuple of polynomials M₁(x), . . . , Mₜ(x), and Gᵢ(x) is the annihilator polynomial of the i'th recovery set.

26. The method according to claim 21 wherein at least two recovery sets of the multiple recovery sets differ from each other by size.

27. The method according to claim 21 wherein all recovery sets of the multiple recovery sets have a same size.

28. A method for encoding multiple data symbols that belong to a finite field F, the method comprising:
receiving or calculating, by a computerized system, multiple (k) input data symbols; wherein the multiple input data symbols belong to a finite field F of order q;
processing the multiple (k) data symbols to provide multiple (n) encoded data symbols that form multiple (t) recovery sets; and
reconstructing a failed encoded symbol of the multiple (n) encoded data symbols;
wherein the reconstructing comprises attempting to reconstruct the failed encoded symbol by utilizing non-failed encoded symbols of at least two recovery sets that are associated with the failed encoded symbol; wherein the at least two recovery sets belong to the multiple recovery sets.

29. The method according to claim 28 wherein the reconstructing comprises:
performing a first attempt to reconstruct the failed encoded symbol by utilizing non-failed encoded symbols of a first recovery set of the at least two recovery sets;
determining whether the first attempt failed; and
performing a second attempt to reconstruct the failed encoded symbol by utilizing non-failed encoded symbols of a second recovery set of the at least two recovery sets if it is determined that the first attempt failed.

30. The method according to claim 28 wherein a number of recovery sets exceeds two; wherein the reconstructing comprises:
performing a first attempt to reconstruct the failed encoded symbol by utilizing non-failed encoded symbols of a first recovery set of the at least two recovery sets;
determining whether the first attempt failed; and
performing multiple additional attempts to reconstruct the failed encoded symbol by utilizing non-failed encoded symbols of a multiple other recovery set of the at least two recovery sets if it is determined that the first attempt failed.
